(19) United States
(12) Patent Application Publication
(10) Pub. No.: US 2026/0040544 A1
(43) Pub. Date: Feb. 5, 2026

(54) METHODS OF FORMING MICROELECTRONIC DEVICES, AND RELATED MICROELECTRONIC DEVICES

(71) Applicant: Micron Technology, Inc., Boise, ID (US)

(72) Inventors: Anna Maria Conti, Milano (IT); Paolo Fantini, Vimercate (IT); Christophe Vincent Antoine Laurent, Agrate Brianza (IT); Paolo Tessariol, Arcore (IT); Andrea Martinelli, Bergamo (IT); Efrem Bolandrina, Fiorano Al Serio (IT)

(21) Appl. No.: 19/254,565

(22) Filed: Jun. 30, 2025

Related U.S. Application Data
(60) Provisional application No. 63/677,967, filed on Jul. 31, 2024.

(51) Int. Cl. H10B 43/20; H10B 41/20; H10B 41/35; H10B 43/35

(52) U.S. Cl. CPC H10B 43/20; H10B 41/20; H10B 41/35; H10B 43/35

(57) ABSTRACT

Forming a microelectronic devices forming a stack structure comprising a vertically alternating sequence of insulative structures and other insulative structures arranged in tiers, forming a pattern of openings in the stack structure, the openings extending into the stack structure from an uppermost surface of the stack structure, the pattern of openings including first groups of openings respectively including openings substantially linearly arranged relative to one another and second groups of openings respectively including additional openings horizontally arranged relative to one another in a dog-bone shape, merging the openings within respective first groups of openings together to form slots, and merging the additional openings within respective second group of openings to form merged openings individually including a central elongated portion and two wide end portions at opposing horizontal ends of the central elongated portion.

### CROSS-REFERENCE TO RELATED APPLICATION

This application claims the benefit under 35 U.S.C. § 119(e) of U.S. Provisional Patent Application Ser. No. 63/677,967, filed Mar. 31, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

FIG. 1 shows a schematic, top-down view of a portion of a microelectronic device, according to one or more embodiments of the disclosure;

FIG. 2 through FIG. 12 show various simplified views of a microelectronic device at different processing stages of a method of forming the microelectronic device, according to one or more embodiments of the disclosure;

FIG. 13 shows a partial cutaway perspective view of a portion of a microelectronic device (e.g., a memory device, such as a dual deck 3D NAND Flash memory device) that may be formed according to the processes described in regard to FIG. 1 through FIG. 12;

FIG. 14A shows a top-down view of an arrangement of multi-gate thin film transistors formed within a thin film transistor region of a microelectronic device, according to one or more embodiments;

FIG. 14B shows a schematic diagram of one of the multi-gate thin film transistors shown in FIG. 14A;

FIG. 15A shows a top-down view of an arrangement of multi-gate thin film transistors within a thin film transistor region of a microelectronic device, according to one or more embodiments;

FIG. 15B shows a schematic diagram of one of the multi-gate thin film transistors shown in FIG. 15A;

FIGS. 16 through 19 show top-down views of different arrangements of thin film transistors within thin film transistor regions of microelectronic devices, according to various embodiments; and

FIG. 20 is a block diagram of an electronic system, in accordance with embodiments of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate to a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process, but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “dog-bone shape” may refer to a shape including a central elongated portion that is elongated in a first direction, and two wide end portions defined at opposite horizontal ends of the central elongated portion. In particular, each of the two wide end portions is defined at a respective end of the central elongated portion in the first direction (i.e., the direction in which the central elongated portion is elongated). Additionally, the two wide end portions are wider than the central elongated portion in a second direction orthogonal to the first direction. Furthermore, each of the central elongated portion and the two wide end portions are at least substantially symmetrical about a central longitudinal axis extending in the first direction.

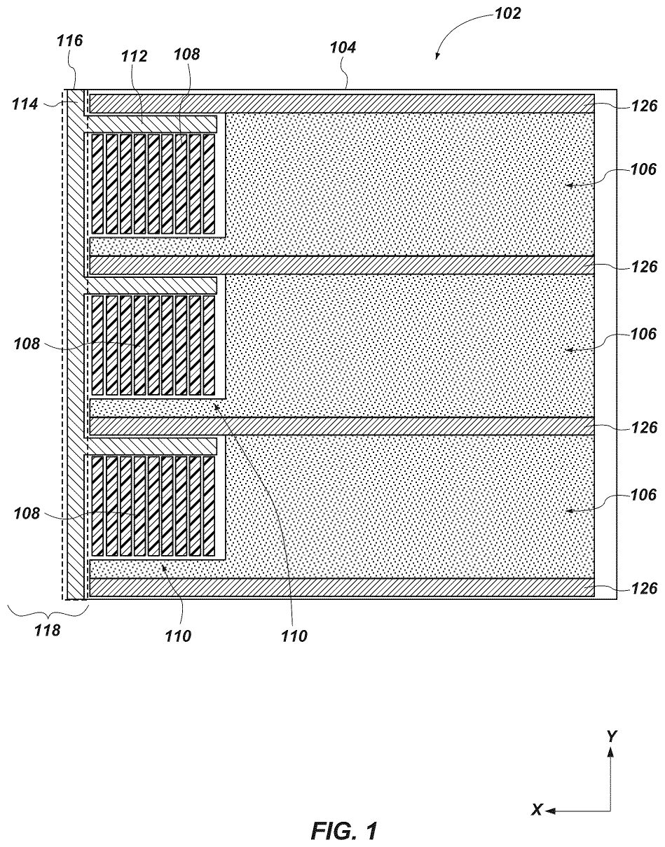

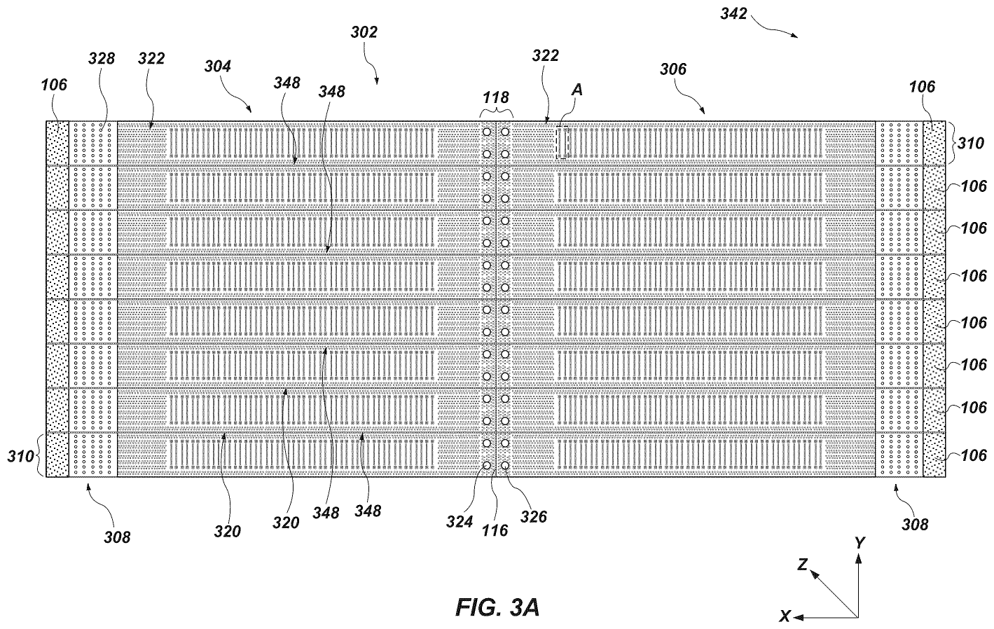

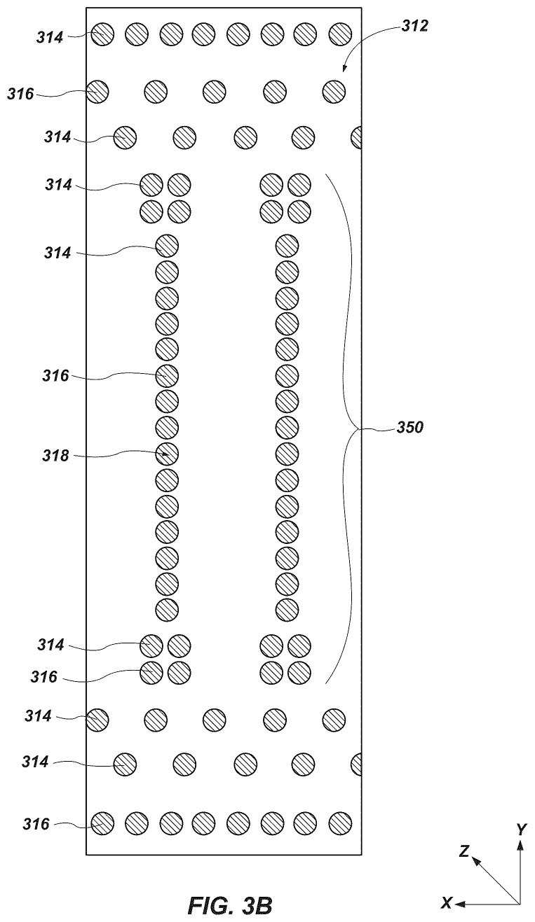

FIG. 1 shows a schematic, top-down view of a portion of a microelectronic device 102 according to one or more embodiments of the disclosure. The microelectronic device 102 may include at least one deck 104 (e.g., stack structure) including a vertically (e.g., in the Z-direction) alternating sequence of insulative material and conductive material arranged in tiers. Each of the tiers may individually include a level of the insulative material directly vertically neighboring (e.g., adjacent) a level of the conductive material. The at least one deck 104 and its formation are described in greater detail below in regard to FIG. 3A through FIG. 12.

The deck 104 may be divided into blocks 106 separated from one another by slot structures 126 (e.g., dielectric slot structures). In addition, groups of thin film transistors 108 and a stack of global word lines 114 may be positioned within a vertical extent of the deck 104 (and, hence, of the blocks 106 thereof). The blocks 106 may respectively include local word lines 110 formed by conductive material of the tiers of the deck 104, and arrays of memory cells operatively associated with the local word lines 110. The thin film transistors 108 may horizontally extend between the local word lines 110 and extensions 112 of the stack of global word lines 114.

The arrays of memory cells (e.g., non-volatile memory cells) of respective ones of the blocks 106 may be positioned within array regions of the blocks 106 horizontally offset (e.g., in the X-direction) from the thin film transistors 108. For example, the blocks 106 may individually include arrays of floating gate cells or charge trap cells. In some embodiments, the memory cells of the blocks 106 are stacked vertically, forming multiple tiers (e.g., layers) of memory cells. For example, arrays of memory cells of the blocks 106 may include vertically extending strings of memory cells, wherein and individual vertically extending string of memory cells includes multiple memory cells vertically stacked relative to one another and in series with one another.

The thin film transistors 108 may serve as select transistors for the blocks 106 (e.g., transistors for controlling read and write operations). During use and operation of the microelectronic device 102, the thin film transistors 108 may facilitate desired transmission of signals from the global word lines 114 to the local word lines 110 (and, hence, the memory cells) of the blocks 106. The thin film transistors 108 may enable precise addressing of specific memory cells of the blocks 106 during data retrieval and programming.

Within the view depicted in FIG. 1, portions of the local word lines 110 may horizontally project from relatively larger regions of the blocks 106 in a first direction (e.g., an X-direction), and the extensions 112 may horizontally extend from the global word lines 114 in the first direction (e.g., the X-direction) that is parallel to the first direction. Furthermore, the thin film transistors 108 may horizontally extend between and be coupled to a given local word line 110 and a respective extension 112 of a respective global word line 114. The thin film transistors 108 may horizontally extend in a second direction (e.g., a Y-direction) that is perpendicular to the first direction.

The deck 104 may further include so-called “staircase” (or “stair step”) structures 116 at an edge (e.g., horizontal end) of the tiers of the deck 104 (e.g., within a staircase structure region 118 of the microelectronic device 102). The staircase structures 116 may respectively include individual “steps” defining contact regions for the global word lines 114 (and, hence, the extensions 112 associated therewith). Contact structures may land on treads of the steps of the staircase structures 116 to facilitate electrical communication between the global word lines 114 and control logic circuitry vertically positioned above and/or below the deck 104. Furthermore, the stack of global word lines 114 may be located proximate the edge of the deck 104 and at least partially within a horizontal area of the staircase structure region 118 of the microelectronic device 102. The global word lines 114 may respectively be connected, through the extensions 112, to the thin film transistors 108 positioned within the vertical extent of the deck 104. The thin film transistors 108 may facilitate selective electrical communication between the global word lines 114 and the local word lines 110.

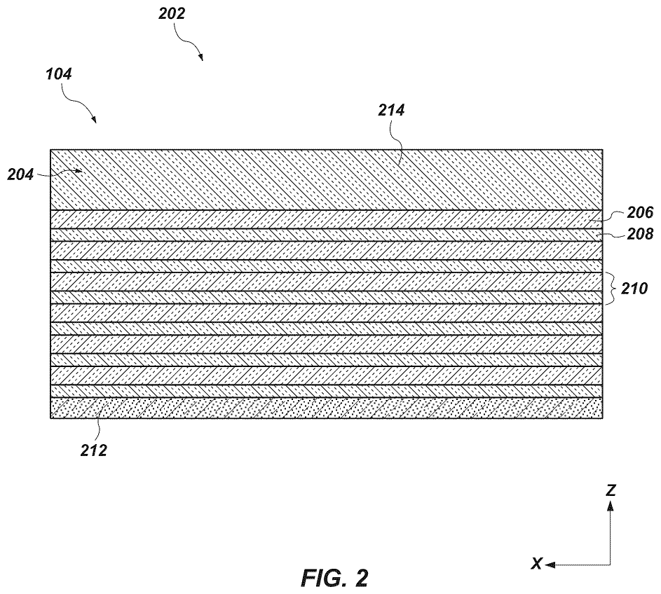

FIG. 2 through FIG. 12 are various views (described in more detail below) showing a method of forming a microelectronic device (e.g., microelectronic device 102 (FIG. 1)), in accordance with embodiments of the disclosure. FIG. 2 is a simplified partial vertical cross-sectional view of a microelectronic device structure 202, in accordance with embodiments of the disclosure. The microelectronic device structure 202 may include a stack structure 204 (to become the deck 104 (FIG. 1)), including a vertically (e.g., in the Z-direction) alternating sequence of insulative material 206 and other insulative material 208 arranged in tiers 210. Each of the tiers 210 may individually include a level of the insulative material 206 vertically neighboring (e.g., adjacent) a level of the other insulative material 208. The levels of insulative material 206 of the stack structure 204 may also be referred to herein as “insulative structures,” and the levels of other insulative material 208 of the stack structure 204 may also be referred to herein as “other insulative structures.”

In some embodiments, a number (e.g., quantity) of tiers 210 of the stack structure 204 is within a range of from 32 of the tiers 210 to 256 of the tiers 210. In some embodiments, the stack structure 204 includes 128 of the tiers 210. However, the disclosure is not so limited, and the stack structure 204 may include a different number of the tiers 210. In addition, in some embodiments, the stack structure 204 vertically overlies (e.g., in the Z-direction) a source structure 212 and includes multiple (e.g., two, more than two) preliminary deck structures vertically stacked relative to one another and individually including a group (e.g., sub-stack) of the tiers 210 of the insulative material 206 and the other insulative material 208. In some such embodiments, a first preliminary deck structure is separated from a second deck structure by an interdeck region. For example, the stack structure 204 may have a dual deck configuration.

The levels of the insulative material 206 may individually be formed of and include, for example, at least one dielectric material, such as one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃)). In some embodiments, the insulative material 206 is formed of and includes silicon dioxide.

The levels of the other insulative material 208 may individually be formed of and include an insulative material that is different than, and exhibits an etch selectivity with respect to, the insulative material 206. In some embodiments, the other insulative material 208 are formed of and include a dielectric nitride material (e.g., silicon nitride (Si₃N₄)) or a dielectric oxynitride material (e.g., silicon oxynitride). In some embodiments, the other insulative material 208 is formed of and includes silicon nitride.

The stack structure 204 may be formed over the source structure 212 (e.g., a source material, a source plate). The source structure 212 may be formed of and include, for example, one or more of conductive material and a doped semiconductor material (e.g., semiconductor material doped with one or more P-type conductivity materials, such as polysilicon doped with one or more of boron, aluminum, and gallium; semiconductor material doped with one or more N-type conductivity materials, such as one or more of arsenic, phosphorous, antimony, and bismuth). Although FIG. 2 has been described and illustrated as including the stack structure 204 directly over (e.g., on) the source structure 212, the disclosure is not so limited. In other embodiments, one or more features (e.g., materials, structures) are vertically interposed between the stack structure 204 and the source structure 212.

A dielectric material 214 may be located over an uppermost one of the tiers 210. The dielectric material 214 may be formed of and include insulative material, such as, for example, one or more of phosphosilicate glass (PSG), borosilicate glass (BSG), fluorosilicate glass (FSG), borophosphosilicate glass (BPSG), and silicon dioxide. In some embodiments, the dielectric material 214 includes the same material composition as the insulative material 206. In some embodiments, the dielectric material 214 is formed of and includes silicon dioxide.

FIG. 3A is a top view of a microelectronic device structure 302 formed from the microelectronic device structure 202 of FIG. 2 through additional processing acts, which are described below. FIG. 3B is an enlarged partial view of the area of the microelectronic device structure 302 of FIG. 3A within box A of FIG. 3A. Referring to FIG. 3A and FIG. 3B together, the microelectronic device structure 302 may include a first block region 304 and a second block region 306 at opposing sides of a staircase structure region 118 (and, hence, of associated staircase structures 116 thereof). For example, the first block region 304 and the second block region 306 may be horizontally separated by the staircase structure region 118 in the X-direction. Each of the first block region 304 and the second block region 306 may include one or more stack structures, such as the stack structure 204 described above in regard to FIG. 2. Within each of the first block region 304 and the second block region 306, the stack structure(s) 204 may be divided into blocks 106 having horizontal ends proximate the staircase structure region 118 in the X-direction.

Individual blocks 106 of the first block region 304 and the second block region 306 may respectively include an in-tier control circuitry region 348, a select gate drain (SGD) contact region 308, and a memory array region 310. The in-tier control circuitry region 348 of an individual block 106 may include a portion of the block 106 to directly horizontally neighbor select transistors (e.g., the select transistors 108 (FIG. 1)) and associated control circuitry to be formed at vertical elevations of the tier 210 (FIG. 2) of the microelectronic device structure 302. The SGD contact region 308 of an individual block 106 may include additional staircase structures at ends of tiers 210 (FIG. 2) to be employed as SGD tiers for the block 106. Conductive contacts (e.g., SGD contacts) may be formed to land on treads of steps of the additional staircase structures, as described in further detail below. In addition, the memory array region 310 of an individual block 106 may include an array of cell pillar structures. Following a subsequent process, intersections of the cell pillar structures of subsequently formed local word lines (e.g., the local word lines 110 (FIG. 1)) of the block may define strings of memory cells of the block 106. As shown in FIG. 3A, for an individual block 106, the SGD contact region 308 may be horizontally interposed between the memory array region 310 of the block 106 and the staircase structure region 118 of the microelectronic device structure 302. Individual blocks 106 of the first block region 304 and the second block region 306 may also respectively include additional regions (e.g., in-tier control circuitry regions, support regions), as described in further detail below.

Referring to FIG. 3A and FIG. 3B together, within horizontal spans (e.g., in the X-direction) of the in-tier control circuitry regions 348 of the blocks 106 (e.g., both of the first block region 304 and the second block region 306), the microelectronic device structure 302 may include a pattern 312 of openings 314 formed within the tiers 210 (FIG. 2) of the stack structure 204 (FIG. 2) thereof. As used herein, the pattern 312 may refer to an arrangement, including orientations and positions, of the openings 314 relative to one another within the XY plane depicted in FIGS. 3A and 3B. The openings 314 may vertically extend (e.g., in the Z-direction) through the insulative material 206 (FIG. 2) and the other insulative material 208 (FIG. 2) of the tiers 210 (FIG. 2) of the stack structure 204 (FIG. 2) within horizontal areas of the first block region 304 and the second block region 306. For instance, in some embodiments, the openings 314 extend entirely through the stack structure 204 (FIG. 2) within each of the first block region 304 and the second block region 306 in the Z-direction to the source structure 212 (FIG. 2). As is described in greater detail below, the pattern 312 may include groups of openings 314, where the openings 314 within each group are horizontally positioned relative to one another to facilitate the sub-sequent formation of relative larger openings therefrom that are then utilized to form desired features (e.g., thin film transistors, slot structures).

The openings 314 of the pattern 312 may be formed utilizing a mask structure (e.g., a patterned photoresist material, a patterned hard mask material) with the pattern 312 of the openings 314 defined therein. For example, the pattern 312 may be defined in a photoresist material (e.g., through selective light exposure using a reticle followed by development) to form a patterned photoresist material, and then the patterned photoresist material may be used to etch the pattern 312 through the stack structure 204 (FIG. 2) to define the openings 314 in the first block region 304 and the second block region 306. For instance, the openings 314 may be formed via one or more directional etches (i.e., anisotropic etches). Additionally, when the stack structure 204 (FIG. 2) of the microelectronic device structure 302 includes multiple preliminary deck structures stacked on top of each other in the Z-direction, the openings 314 may be formed in each preliminary deck structure, respectively. For example, upon formation of a first preliminary deck structure (e.g., lowermost preliminary deck structure), the openings 314 are formed in the first preliminary deck structure and filled (described below). Subsequently, a second preliminary deck structure is formed above the first preliminary deck structure, and more of the openings 314 are formed in the second preliminary deck structure and filled. Any further preliminary deck structures formed above the second preliminary deck structure may have further openings 314 formed therein and filled in the same manner. In other words, the openings 314 may be formed and then filled on a deck-by-deck basis.

After forming the openings 314, the openings 314 may be filled with sacrificial material 316. For instance, the sacrificial material 316 may be deposited within the openings 314 through a spin-on coating process. In some embodiments, the sacrificial material 316 is a spin-on carbon. In other embodiments, the sacrificial material 316 is deposited through any of the other deposition methods described herein. In some embodiments, some openings 314 are filled with a first sacrificial material and other openings 314 are filled with a second sacrificial material. Filling the openings 314 with the sacrificial material 316 may form pillars 318 (i.e., pillars of the sacrificial material 316) within the openings 314.

As noted above, the pattern 312 of openings 314 may partially define shapes for relatively larger openings to be formed and utilized to form additional features within the microelectronic device structure 302. For instance, the pattern 312 of openings 314 may include first groups of openings 314 at least partially defining slot regions 320 extending in the X-direction and at least partially defining horizontal areas of the blocks 106. Additionally, referring specifically to FIG. 3B, the pattern 312 of openings 314 may include second groups 350 of openings 314 at least partially defining shapes (e.g., dog-bone shapes) for relatively larger openings.

Furthermore, as shown in FIG. 3A, the blocks 106 within each of the first block region 304 and the second block region 306 may also include support regions 322. Within an individual block 106, one support region 322 may be horizontally interposed (e.g., in the X-direction) between the in-tier control circuitry region 348 of the block 106 and the staircase structure region 118 of the microelectronic device structure 302; and one other support region 322 may be horizontally interposed (e.g., in the X-direction) between the in-tier control circuitry region 348 of the block 106 and the SGD contact region 308 of the block 106. The sacrificial material 316 filling the openings 314 within the support regions 322 may form support pillars 318 within the blocks 106.

Within the staircase structure region 118 of the microelectronic device structure 302, word line contact openings 324 may be formed to provide access to the individual steps of the staircase structures 116 of the staircase structure region 118. The word line contact openings 324 may be formed separate from the openings 314 (e.g., formed through a different etch process than the openings 314). In some embodiments, the word line contact openings 324 are formed by using one or more masks and anisotropic etches. Additionally, the word line contact openings 324 may be subsequently filled with a second sacrificial material 326 through any of the deposition processes described herein. The second sacrificial material 326 may include any of the sacrificial materials described herein, such as carbon (C).

The SGD contact regions 308 of the blocks 106 within both the first block region 304 and the second block region 306 may include dummy pillars 328 vertically extending (e.g., in the Z-direction) therethrough. As described in greater detail below, the dummy pillars 328 may later be replaced with a conductive material to form SGD contacts.

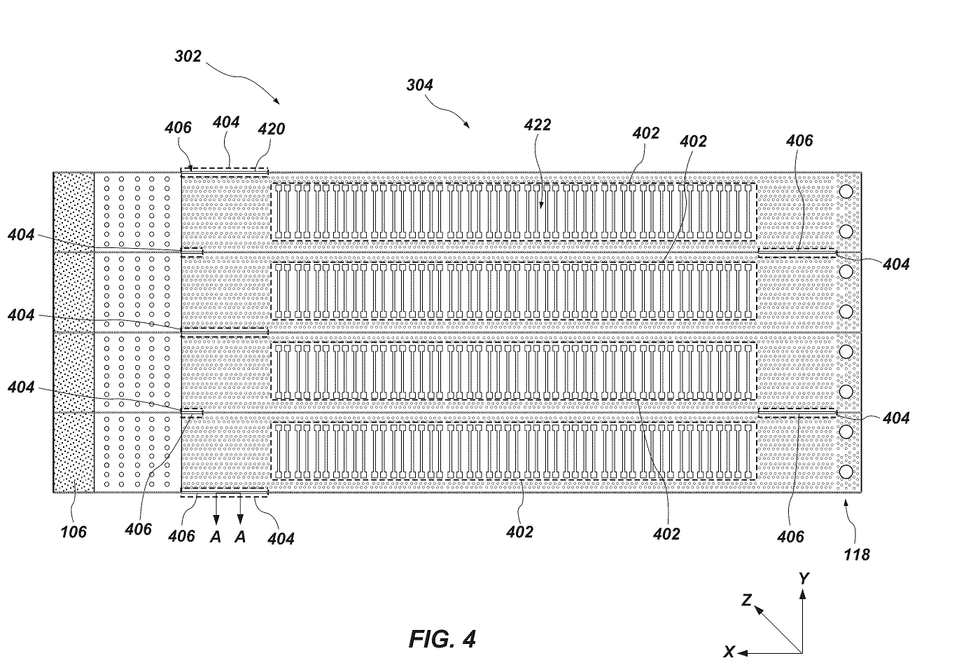

FIG. 4 shows a top schematic view of the first block region 304 of the microelectronic device structure 302 at a processing stage following that previously described with reference to FIGS. 3A and 3B, according to one or more embodiments of the disclosure. While only the first block region 304 is depicted, the following description is equally applicable to the second block region 306. Referring to FIG. 4, each of the first block region 304 and the second block region 306 may include thin film transistor regions 402 and first slot regions 404. The first slot regions 404 (i.e., block isolation regions) may be between neighboring blocks 106 in the Y-direction. The thin film transistor regions 402 may horizontally neighbor the support regions 322 (FIG. 3A) of the blocks 106 in the X-direction and may horizontally neighbor the in-tier control circuitry regions 348 (FIG. 3A) of the blocks 106 in the Y-direction.

The first slot regions 404 may include first groups of openings 314 forming first slot shapes 420 for ultimately formed isolation structures. For example, the first groups of openings 314 within the first slot regions 404 may respectively have openings 314 arranged next to each other in a general shape (e.g., first slot shape 420) of ultimately formed isolation structures (e.g., slot structures). As a non-limiting example, the openings 314 of each first group of openings 314 may be arranged relative to one another so as to form a generally linear shape. Additionally, the thin film transistor regions 402 may include second groups 350 (FIG. 3B) of openings 314 forming second slot shapes 422 for ultimately formed thin film transistors. For instance, the second groups 350 (FIG. 3B) of openings 314 within the thin film transistor regions 402 may respectively have openings 314 arranged next to each other in a general shape (e.g., second slot shape 422) of ultimately formed thin film transistors. As a non-limiting example, the openings 314 of each second group of openings 314 may be arranged relative to one another so as to form a dog-bone shape.

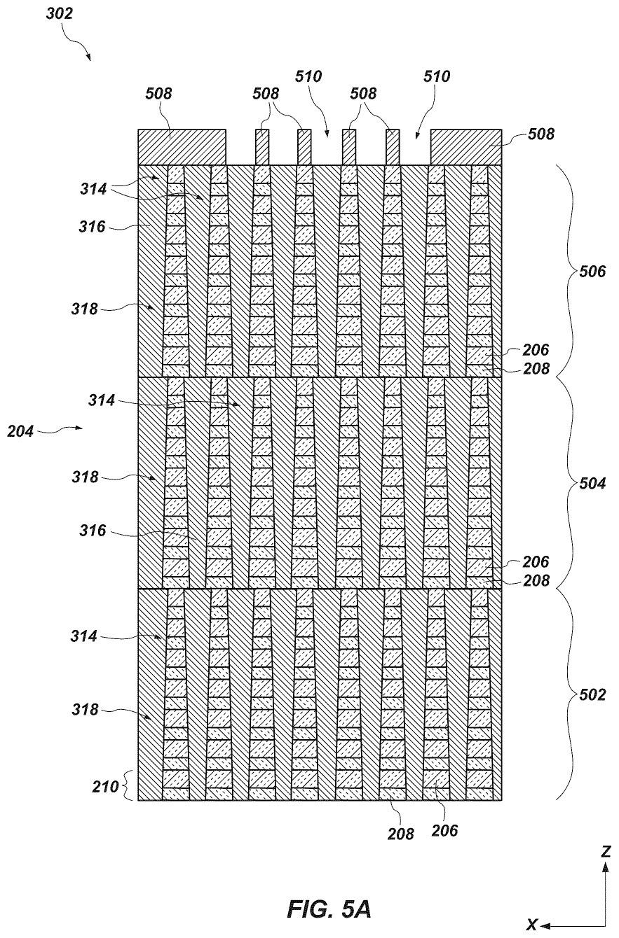

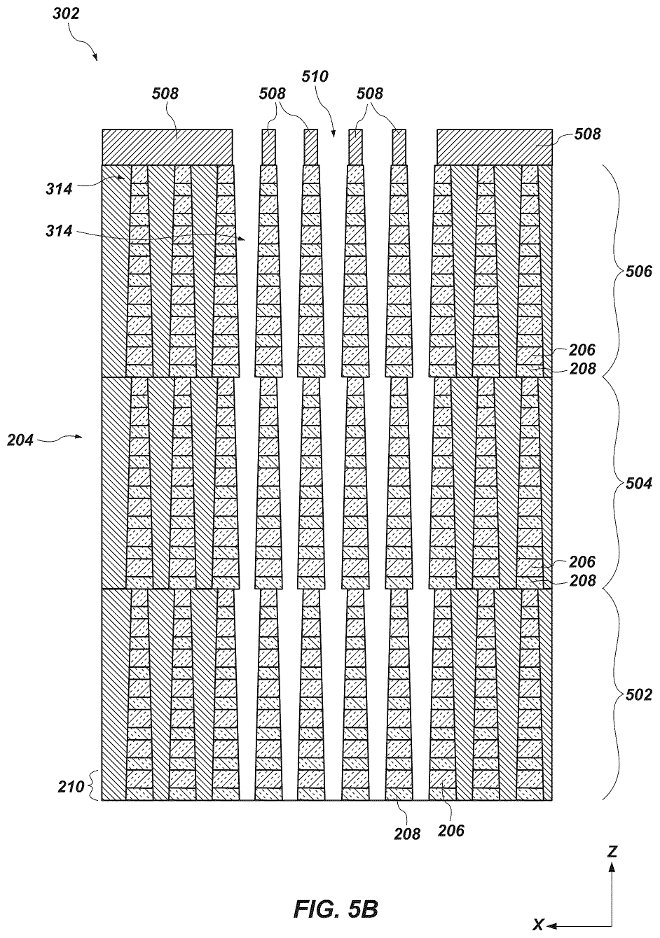

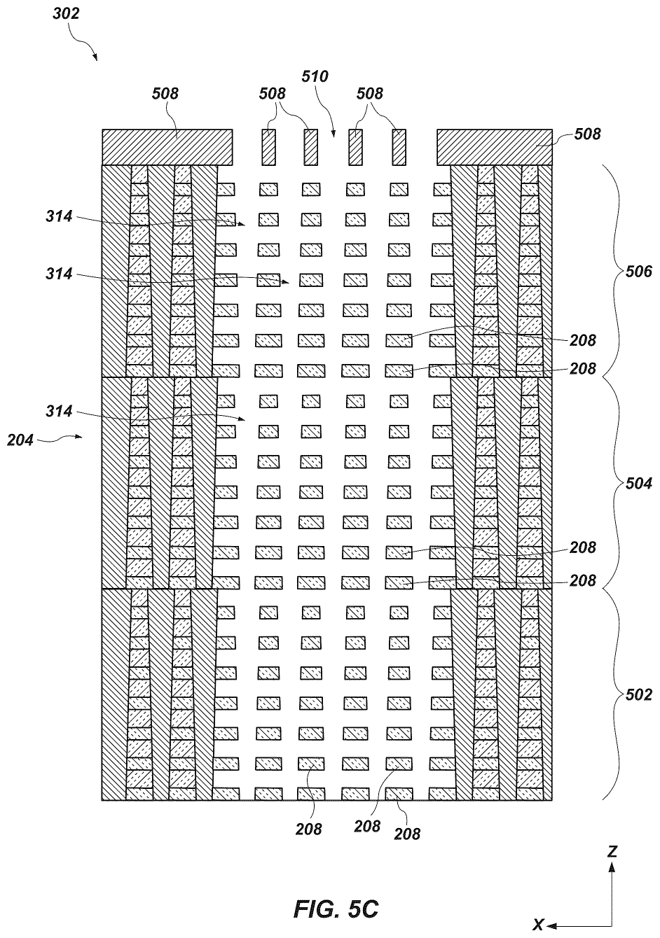

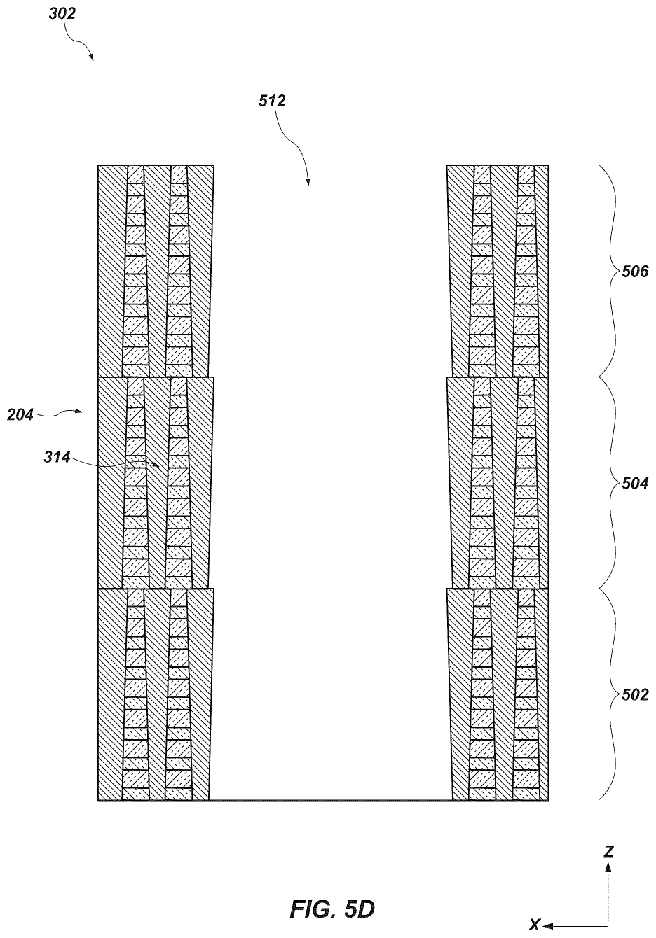

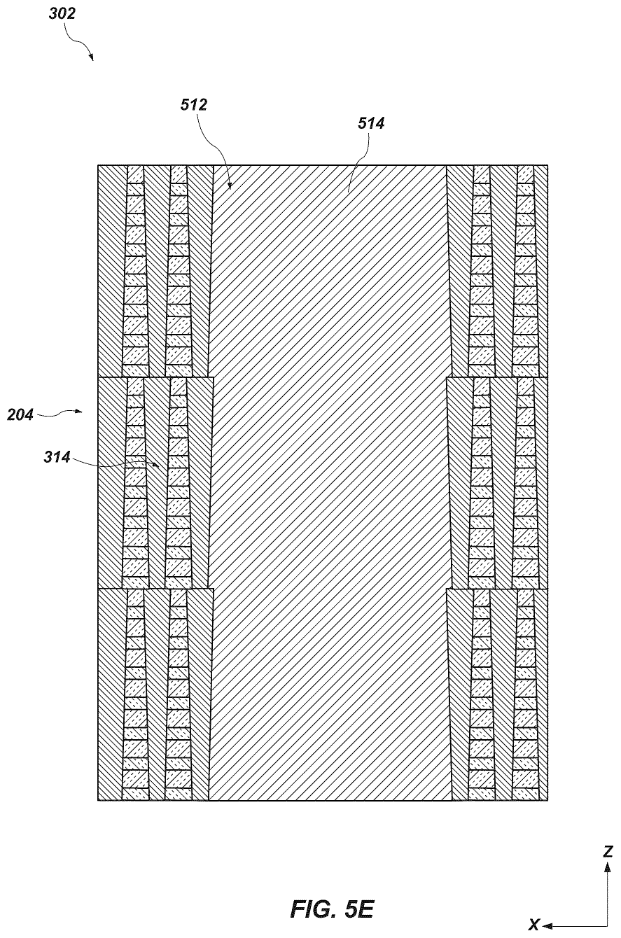

As is described in greater detail below, each second group 350 (FIG. 3B) of openings 314 within the thin film transistor regions 402, and each first group of openings 314 within the first slot regions 404, may respectively be merged together to define larger openings. As a non-limiting example, the openings 314 of each second group 350 of openings 314 within the thin film transistor regions 402 may be merged together to define larger openings utilized to form later-formed thin film transistors. Additionally, the openings 314 of each first group of openings 314 within the first slot regions 404 may be merged together to define larger openings utilized to form later-formed first isolation structures. The process of merging openings 314 is described in detail below in regard to FIG. 5A through FIG. 5E.

FIG. 5A through FIG. 5E include simplified, vertical cross-sectional views of an example portion of the microelectronic device structure 302 taken about line A-A of FIG. 4, at different processing stages of merging various openings 314 together. Furthermore, while line A-A is depicted across a portion of a first group of openings 314 within a first slot region 404 of the microelectronic device structure 302 and includes openings 314 utilized to form a first slot structure, the second groups 350 (FIG. 3B) of openings 314 within the thin film transistor regions 402 may be merged through a same process. Moreover, while FIG. 5A through FIG. 5E depict only five openings 314 for simplicity and to enable showing enlarged structures and details within the drawings, any number of openings 314 may be merged together through the processes described. FIG. 5A may represent a structure of the microelectronic device structure 302 after the processing steps described above in regard to FIG. 3A and FIG. 3B.

Referring specifically to FIG. 4 and FIG. 5A together, multiple preliminary deck structures are shown stacked above one another (e.g., a first preliminary deck structure 502, a second preliminary deck structure 504 stacked over the first deck 502, and a third preliminary deck structure 506 stacked above the second deck 504). Each of the preliminary deck structures 502, 504, 506 constitutes a portion of the overall stack structure 204; and includes some of the tiers 210 of insulative material 206 and other insulative material 208, and openings 314 vertically extending through the some of the tiers 210 thereof in the Z-direction. The openings 314 are filled with the sacrificial material 316, forming the pillars 318. As used herein, “openings” will be understood to include both unfilled openings (e.g., void spaces) and filled openings.

As noted above, the first groups of openings 314 and the second groups of openings 314 in the respective regions may be merged together using one or more etching processes. For instance, a first mask material 508 may be formed over the top surface of the stack structure 204 (i.e., on a top surface of the third preliminary deck structures 506), and the first mask material 508 may be patterned to form first patterned openings 510 at least partially horizontally overlapping the openings 314 of the first and/or second groups of openings 314 (e.g., selected openings 314) within the thin film transistor regions 402 and the first slot regions 404. The first mask material 508 may be patterned to include the first patterned openings 510 utilizing any suitable methodology. For instance, in some embodiments, a photoresist material is formed on or over the first mask material 508, is patterned (e.g., photo exposed and developed), and then openings formed in the patterned photoresist material are extended into the first mask material 508 to form the first patterned openings 510. The first mask material 508 may be removed during subsequent processing stages, or may remain in a final device formed through the methods of the disclosure. The first mask material 508 may be formed of and include dielectric material, such as dielectric nitride material (e.g., silicide nitride).

Referring to FIG. 4 and FIG. 5B together, the first mask material 508 and the first patterned openings 510 may be employed to remove the sacrificial material 316 within the openings 314 through one or more etch processes. For instance, the sacrificial material 316 may be removed from the openings 314 horizontally overlapping the first patterned openings 510 using an etching process (e.g., an anisotropic etching process) that selectively removes exposed portions of the sacrificial material 316 without removing portions of the insulative material 206 and the other insulative material 208 of the tiers 210. Furthermore, the sacrificial material 316 within the openings 314 of each of the first preliminary deck structure 502, the second preliminary deck structure 504, and the third preliminary deck structure 506 may be removed through a single etching process. Accordingly, respective openings 314 within the first preliminary deck structure 502, the second preliminary deck structure 504, and the third preliminary deck structure 506 that horizontally overlap one another (e.g., in the X-direction) may be merged together in a vertical direction (e.g., in the Z-direction).

Referring to FIG. 4 and FIG. 5C together, the insulative material 206 (FIG. 5B) horizontally interposed between the openings 314 (e.g., interposed between the openings 314 in the X-direction and/or Y-direction) may be removed. For example, the insulative material 206 may be removed using an etching process (e.g., isotropic etching process) that selectively removes exposed portions of the insulative material 206 (e.g., oxide material) without substantially removing portions of the other insulative material 208 (e.g., nitride material). In some embodiments, the insulative material 206 is removed using an oxide recess etching process. In some embodiments, the insulative material 206 of the tiers 210 of each of the first preliminary deck structure 502, the second preliminary deck structure 504, and the third preliminary deck structure 506 are removed substantially simultaneously.

Referring to FIG. 4 and FIG. 5D together, the other insulative material 208 (FIG. 5C) horizontally interposed between the openings 314 may also be removed. By way of non-limiting example, the other insulative material 208 may be removed by exposing the other insulative material 208 to an etchant (e.g., a wet etchant) including one or more of phosphoric acid, sulfuric acid, hydrochloric acid, nitric acid, or another material. In some embodiments, the other insulative material 208 is removed by exposing the other insulative material 208 to a so-called “wet nitride strip” comprising phosphoric acid. In some embodiments, the other insulative material 208 of each of the first preliminary deck structure 502, the second preliminary deck structure 504, and the third preliminary deck structure 506 are removed substantially simultaneously. In some embodiments, remaining portions of the first mask material 508 are then removed by way of a CMP process.

As is shown in FIG. 5D, by removing the insulative material 206 (FIG. 5B) and the other insulative material 208 (FIG. 5C) horizontally interposed between select ones of the openings 314 (FIG. 5C), a larger merged opening 512 may be defined extending vertically through the first preliminary deck structure 502, the second preliminary deck structure 504, and the third preliminary deck structure 506. As is mentioned briefly above, these larger merged openings 512 may individually be utilized to form a thin film transistor 108 (FIG. 1) or a first slot structure.

Referring to FIG. 4 and FIG. 5E together, the larger, merged openings 512 may be filled with fill material 514. For instance, the fill material 514 may be formed (e.g., deposited) by way of the manners described herein.

For merged openings 512 to be utilized to form thin film transistors 108 (FIG. 1), the fill material 514 may include a sacrificial material (e.g., carbon). For merged openings 512 (i.e., first slots 420) being utilized to form first slot structures, the fill material 514, and, as a result, the resulting first slot structures, may include a dielectric material. For example, the fill material 514, and, as a result, the resulting first slot structures, may include one or more of dielectric oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃)). In some embodiments, the fill material 514, and consequently, the resulting first slot structures, are formed of and include silicon dioxide.

By way of the processes described in regard to FIG. 4 through FIG. 5E, merged openings 512 having general shapes of later-formed thin film transistors 108 (FIG. 1) may be formed, and isolation structures (i.e., first slot structures) may also be formed. As is discussed in greater detail below, the isolation structures (i.e., first slot structures) may serve as isolation regions between the blocks 106 and the staircase structure 116, and between the staircase structure 116 and later-formed global word lines 114 (FIG. 1).

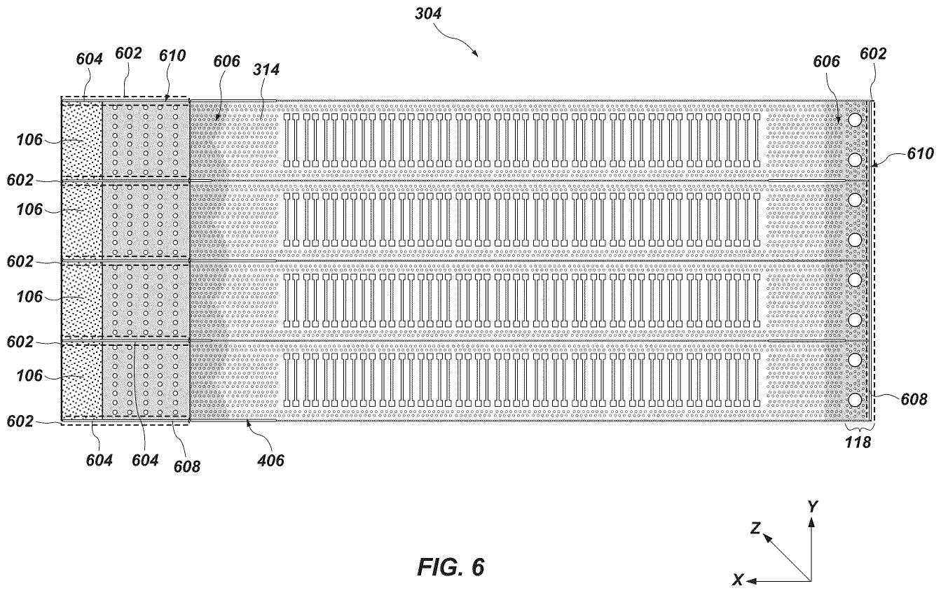

FIG. 6 shows a top schematic view of the first block region 304 following the processing stages previously described with reference to FIGS. 4 through 5E, according to one or more embodiments. Referring to FIG. 6, each of the first block region 304 and the second block region 306 may include first slot structures 406 formed through the process described with reference to FIGS. 5A through 5E, as well as second slot regions 602 (e.g., so-called “replacement gate” slot regions) defined horizontally between the blocks 106 neighboring one another in the Y-direction and within the staircase structure region 118. The second slot regions 602 may respectively be formed to include second slots 604 individually formed from a group of the openings 314 through processing similar to that previously described with reference to FIGS. 5A through 5E for the formation of the merged openings 512 (FIG. 5E). The second slots 604 may be used in one or more so-called “replacement gate” or “gate last” processes. The second slots 604 may individually be formed to have a generally linear shape. The groups of openings 314 utilized to form the second slots 604 within the second slot regions 602 may be referred to as being within the first groups of openings 314 referred to above in regard to FIG. 3A.

As noted above, the second slots 604 may be formed via the processes described above in regard to FIG. 5A through FIG. 5D by merging the openings 314 within the second slot regions 602. Subsequent to forming the second slots 604, portions of the other insulative material 208 (FIG. 2) of the stack structures 204 of the first block region 304 and the second block region 306 relatively proximate the second slots 604 may be removed by way of the second slots 604 as part of a so-called “replacement gate” or “gate last” process. By way of non-limiting example, the portions of the other insulative material 208 (FIG. 2) may be removed by exposing the other insulative material 208 (FIG. 2) to an etchant (e.g., a wet etchant) comprising one or more of phosphoric acid, sulfuric acid, hydrochloric acid, nitric acid, or another material. In some embodiments, the portions of the other insulative material 208 (FIG. 2) are removed by exposing the other insulative material 208 (FIG. 2) to a so-called “wet nitride strip” comprising phosphoric acid.

Referring to FIG. 2 and FIG. 6, after removal of the portions of the other insulative material 208, conductive material 606 may be formed within the resulting void spaces. The conductive material 606 of some of the tiers 210 may serve as portions of local word line structures (e.g., local word lines 110 (FIG. 1)), and the conductive material 606 of some others of the tiers 210 may serve as select gate structures, such as select gate drain (SGD) structures.

The conductive material 606 may be formed of and include one or more of at least one metal (e.g., tungsten, titanium, nickel, platinum, rhodium, ruthenium, iridium, aluminum, copper, molybdenum, silver, gold), at least one alloy, at least one metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), a conductively-doped semiconductor material (e.g., conductively-doped silicon, conductively-doped germanium, conductively-doped silicon germanium), other materials exhibiting electrical conductivity, or combinations thereof. In some embodiments, the conductive material 606 is tungsten.

In some embodiments, the conductive material 606 includes a conductive liner material (not shown) around the conductive material 606, such as between the conductive material 606 and the insulative material 206. The conductive liner material may include, for example, a seed material from which the conductive material 606 may be formed. The conductive liner material may be formed of and include, for example, a metal (e.g., titanium, tantalum), a metal nitride (e.g., tungsten nitride, titanium nitride, tantalum nitride), or another material. In some embodiments, the conductive liner material is titanium nitride.

After forming the conductive material 606, the second slots 604 may be filled with a second dielectric material 608. The second dielectric material 608 may form second slot structures 610. As a result, the second dielectric material 608 (e.g., the second slot structures 610) may physically separate (e.g., isolate) portions (e.g., memory array regions 310, SGD contact regions 308) of horizontally neighboring blocks 106 of the microelectronic device 102 (FIG. 1) from one another in the Y-direction. As shown in FIG. 6, the second slot structures 610 may horizontally overlap (e.g., be substantially horizontally aligned with) the first slot structures 406 in the Y-direction.

The second dielectric material 608 may be formed of and include insulative material such as, for example, phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), a dielectric carbon nitride material (e.g., silicon carbon nitride (SiCN)), a dielectric carboxynitride material (e.g., silicon carboxynitride (SiOCN)), or combinations thereof. In some embodiments, the second dielectric material 608 is formed of and includes silicon dioxide.

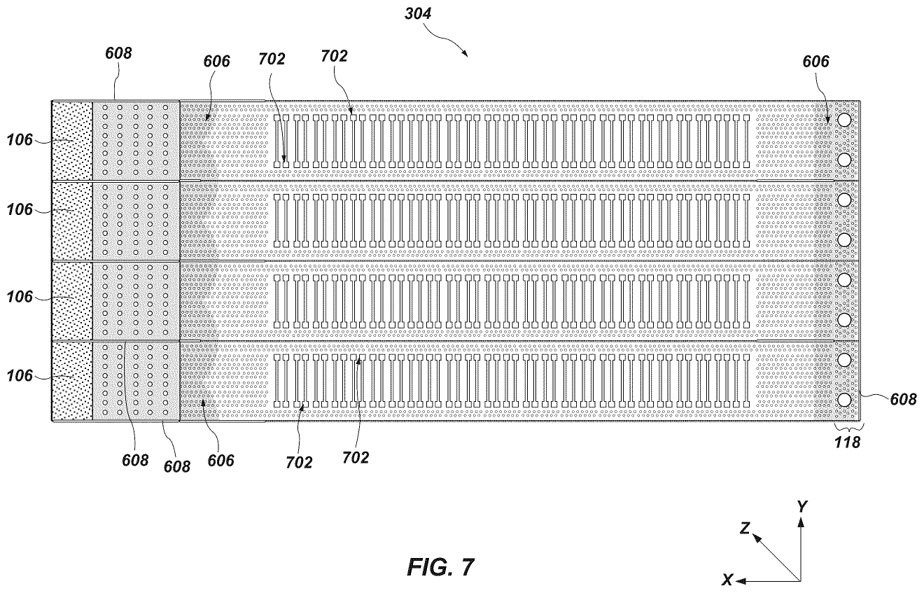

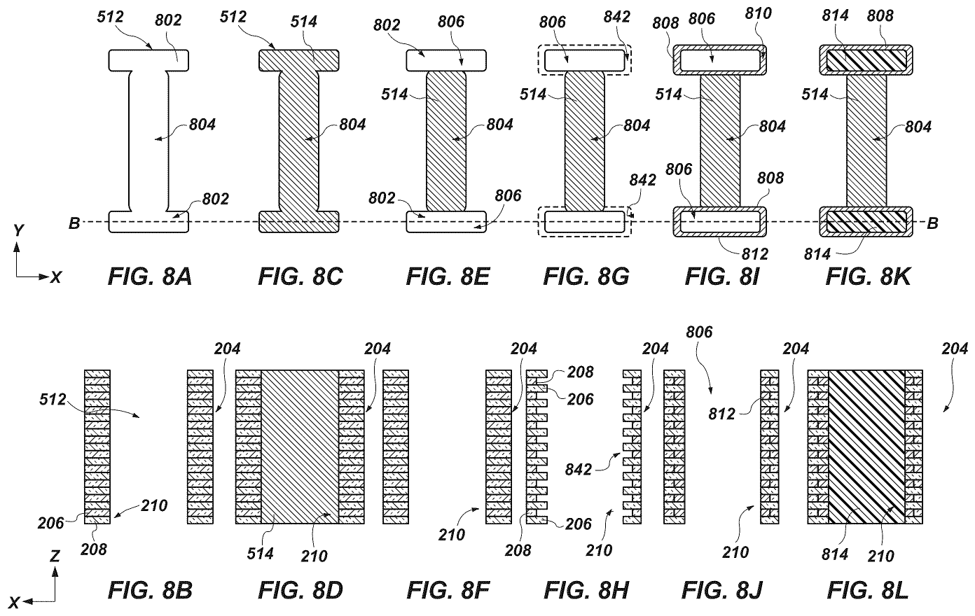

FIG. 7 shows a top schematic view of the first block region 304 following the processing stage previously described with reference to FIG. 6, according to one or more embodiments. As discussed above in regard to FIG. 4 through FIG. 5E, merged openings 512 (FIG. 5E) within the thin film transistor regions 402 may be utilized to form thin film transistors 108 (FIG. 1). Furthermore, as shown in FIG. 7, source and/or drain structures 702 of ultimately formed thin film transistors 108 (FIG. 1) may first be formed within the merged openings 512 of the thin film transistor regions 402. Formation of the source and/or drain structures 702 is described in detail below in regard to FIG. 8A through FIG. 8F.

FIG. 8A through FIG. 8L include simplified, top-down views (FIGS. 8A, 8C, 8E, 8G, 8I, 8K) and simplified, vertical cross-sectional views (FIGS. 8B, 8D, 8F, 8H, 8J, 8L) showing different processing stages of forming the source and/or drain structures 702 of a thin film transistor 108 (FIG. 1). The simplified, vertical cross-sectional views shown in FIGS. 8B, 8D, 8F, 8H, 8J, and 8L are about line B-B shown in FIGS. 8A, 8C, 8E, 8G, 8I, 8K, respectively. FIGS. 8A and 8B collectively depict a first processing stage in the process of forming the source and/or drain structures 702; FIGS. 8C and 8D collectively depict a second processing stage following the first processing stage; FIGS. 8E and 8F collectively depict a third processing stage following the second processing stage; FIGS. 8G and 8H collectively depict a fourth processing stage following the third processing stage; FIGS. 81 and 8J collectively depict a fifth processing stage following the fourth processing stage; and FIGS. 8K and 8L collectively depict a sixth processing stage following the fifth processing stage. FIG. 8A through FIG. 8L show the formation of source and/or drain structures 702 within a single merged opening 512; however, it is understood that the processes described in regard to FIG. 8A through FIG. 8L may be utilized to form source and/or drain structures 702 of multiple merged openings 512 simultaneously and/or consecutively.

Referring collectively to FIG. 8A and FIG. 8B, the merged opening 512 may be formed through the processes described above in regard to FIG. 5A through FIG. 5D for merging openings 314 (FIG. 3B) by way of various etching processes.

As is shown in FIG. 8A, the merged openings 512 utilized to form thin film transistors 108 (FIG. 1) may have a general dog-bone shape within the XY plane. As noted above, the openings 314 (FIG. 3B) within and individual group of openings 314 (FIG. 3B) within the thin film transistor region 402 (FIG. 4) may be arranged relative to one another in a general dog-bone shape. As a result, within the XY plane, an individual merged opening 512 may include two wide end portions 802 defined on opposing ends of a central elongated portion 804 in the Y-direction. The central elongated portion 804 may be elongated in the Y-direction. The wide end portions 802 may each be wider than the central elongated portion 804 in the X-direction. As is discussed in greater detail below, the source and/or drain structures 702 of the thin film transistors 108 (FIG. 1) are formed within the wide end portions 802 of the merged openings 512.

Referring next to FIGS. 8C and 8D, the merged opening 512 may be filled with the fill material 514 through the processes described above in regard to FIG. 5E.

Referring to FIGS. 7, 8E, and 8F together, portions of the fill material 514 within the wide end portions 802 of the merged openings 512 may be removed to form source and/or drain trenches 806. An additional portion of the fill material 514 within the central elongated portion 804 of respective ones of the merged openings 512 may be maintained (e.g., may not be substantially removed).

The portions of the fill material 514 may be removed through any of the removal processes described herein. For example, a mask material may be formed over the top surfaces of the stack structures 204 of the first block region 304 (FIG. 3A) and the second block region 306 (FIG. 3A) (e.g., on a top surface of the third preliminary deck structure 506 (FIG. 5A)), and the mask material may be patterned to form openings horizontally aligned with the wide end portions 802 of the merged openings 512 within the thin film transistor regions 402 (FIG. 4). The mask material may be patterned to include the patterned openings utilizing any suitable methodology. For instance, in some embodiments, a photoresist material is formed on or over the mask material, is patterned (e.g., photo exposed and developed), and then openings formed in the patterned photoresist material are extended into the mask material to form the patterned openings. The mask material may be removed during subsequent processing stages or may remain in a final device formed through the methods of the disclosure. The mask material may be formed of and include a dielectric material, such as a dielectric nitride material (e.g., silicide nitride).

The mask material and the patterned openings may be employed to remove the portions of the fill material 514 within the wide end portions 802 of the merged openings 512 through one or more etch processes. For instance, the portions of the fill material 514 may be removed using an etching process (e.g., an anisotropic etching process) that selectively removes the exposed portions of the fill material 514 without removing portions of the insulative material 206 and the other insulative material 208. Additionally, the portions of the fill material 514 may be removed using a directional etching process that does not significantly etch in horizontal directions (e.g., in the Y- and/or X-directions). Furthermore, the portions fill material 514 within the wide end portions 802 of the merged openings 512 extending through the first preliminary deck structure 502 (FIG. 5E), the second preliminary deck structure 504 (FIG. 5E), and the third preliminary deck structure 506 (FIG. 5E) may be removed through a single etching process or multiple etching processes.

Referring to FIGS. 7, 8G, an 8H together, portions of the other insulative material 208 of respective tiers 210 of the stack structures 204 defining horizontal boundaries of the wide end portions 802 of the merged openings 512 may be removed (e.g., recessed) to form horizontal recesses 842 at vertical positions of the other insulative material 208 of the tiers 210. For example, portions of the other insulative material 208 of the tiers 210 may be removed using a selective etching process (e.g., isotropic etching process) that selectively removes exposed portions of the other insulative material 208 (e.g., dielectric nitride material) without substantially removing portions of the insulative material 206 (e.g., dielectric oxide material) of the tiers 210. In some embodiments, the portions of the other insulative material 208 are removed using a wet nitride removal process. In some embodiments, the portions of the other insulative material 208 of each of the first preliminary deck structure 502 (FIG. 5E), the second preliminary deck structure 504 (FIG. 5E), and the third preliminary deck structure 506 (FIG. 5E) are removed at least substantially simultaneously. The horizontal recesses 842 may be integral and continuous with the source and/or drain trenches 806.

Referring to FIGS. 7, 8I, and 8J, together, semiconductor material 808 may be formed within the horizontal recesses 842 (FIGS. 8G and 8H). As shown in FIG. 8J, the semiconductor material 808 may substantially fill respective ones of the horizontal recesses 842 (FIG. 8H). Portions of the semiconductor material 808 within horizontal areas of the source and/or drain trenches 806 may be removed, such that the semiconductor material 808 is substantially confined within horizontal areas of the horizontal recesses 842 (FIGS. 8G and 8H).

The semiconductor material 808 may be formed (e.g., deposited) through any of the deposition processes described herein. For instance, the semiconductor material 808 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In some embodiments, forming the semiconductor material 808 includes overfilling the vertical spaces between insulative material 206 of the tiers 210 of the stack structures 204 with the semiconductor material 808 and then removing any excess portions through one or more etching processes. For instance, the wide end portions 802 of the merged openings 512, including the vertical spaces between insulative material 206 of the tiers 210 of the stack structures 204, may be filled with the semiconductor material 808, and excess portions of the semiconductor material 808 may be subsequently removed through one or more etches.

Referring still to FIGS. 81 and 8J, by ultimately filling only the horizontal recesses 842 (FIGS. 8G and 8H) with the semiconductor material 808, generally annular-shaped (e.g., block-O shaped) structures of the semiconductor material 808 may be formed within the tiers 210 of the stack structure 204.

Forming the semiconductor material 808 as described above may form first semiconductor structures 810 within a first wide end portion 802 of a given merged opening 512 and second semiconductor structures 812 within a second wide end portion 802 of the given merged opening 512. Furthermore, in some embodiments, each of the first semiconductor structures 810 and each of the second semiconductor structures 812 includes doped semiconductor material. For example, each of the first semiconductor structures 810 and each of the second semiconductor structures 812 may be n-type doped, such as doped to an n-type dopant concentration within a range of from about 10¹⁵ cm⁻³ to about 10²⁰ cm⁻³. In additional embodiments, one of the first semiconductor structures 810 and the second semiconductor structures 812 is an n-type doped while the other of the first semiconductor structures 810 and the second semiconductor structures 812 is p-type doped, such as doped to a p-type dopant concentration within a range of from about −10¹³ cm⁻³ to about −10¹⁸ cm⁻³. In additional embodiments, one or more of the first semiconductor structures 810 and the second semiconductor structures 812 is doped (either p-doped or n-doped) to the point of saturation (e.g., greater than or equal to about −10¹⁸ cm⁻³). The doping may be accomplished utilizing any suitable processing, such as by implanting dopant (e.g., at least one n-type dopant or at least one p-type dopant) into the semiconductor material 808. A p-type dopant may include one or more of boron, aluminum, and gallium; and an n-type dopant may include one or more of arsenic, phosphorous, antimony, and bismuth.

As is discussed in further detail below, in some embodiments, the first semiconductor structures 810 respectively form one of a source structure or a drain structure of a later-formed thin film transistor 108 (FIG. 1); and the second semiconductor structures 812 respectively form another of a source structure or a drain structure of the later-formed thin film transistor 108 (FIG. 1).

Referring to FIGS. 7, 8K, and 8L together, remainders (e.g., unfilled portions) of the source and/or drain trenches 806 may be filled with insulative material 814. For example, the remainders of the source and/or drain trenches 806 may be substantially filled with the insulative material 814 through any of the deposition processes described herein. The insulative material 814 may serve to isolate the annular-shaped structures of the semiconductor material 808 (e.g., the first semiconductor structures 810, the second semiconductor structures 812) of the tiers 210 of the stack structure 204 associated with (e.g., horizontally neighboring) a given wide end portion 802 from each other.

The insulative material 814 may be formed of and include insulative material such as, for example, dielectric oxide material (e.g., phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide), dielectric nitride material (e.g., silicon nitride (Si₃N₄)), dielectric oxynitride material (e.g., silicon oxynitride), dielectric carbon nitride material (e.g., silicon carbon nitride (SiCN)), dielectric carboxynitride material (e.g., silicon carboxynitride (SiOCN)), or combinations thereof. In some embodiments, the insulative material 814 is formed of and includes silicon dioxide.

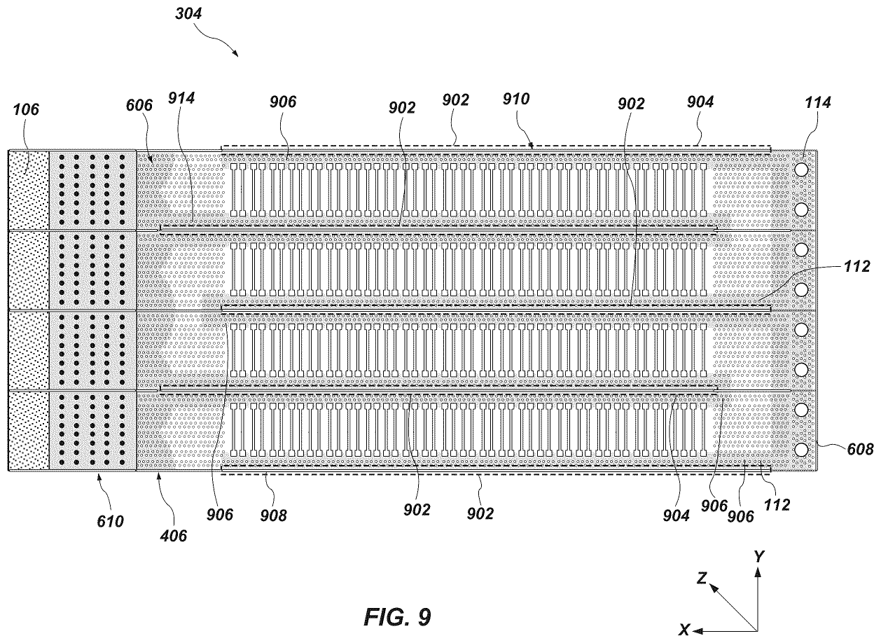

FIG. 9 shows a top schematic view of the first block region 304 following the processing stages previously described with reference to FIGS. 7 and 8A through 8L, according to one or more embodiments. Referring to FIG. 9, each of the first block region 304 and the second block region 306 (FIG. 3A) may include third slot regions 902 (e.g., additional “replacement gate” slot regions) defined horizontally between the in-tier control circuitry regions 348 (FIG. 3A) of the blocks 106 (and, hence, the thin film transistor regions 402 (FIG. 4)) in the Y-direction. The third slot regions 902 may respectively be formed to include third slots 904 individually formed from a group of the openings 314 through processing similar to that previously described with reference to FIGS. 5A through 5E for the formation of the merged openings 512 (FIG. 5E). The third slots 904 may be used in one or more additional “replacement gate” or “gate last” processes. The third slots 904 may individually be formed to have a generally linear shape. The groups of openings 314 utilized to form the third slots 904 within the third slot regions 902 may be referred to as being within the first groups of openings 314 referred to above in regard to FIG. 3A.

The third slots 904 may be formed via the processes described above in regard to FIG. 5A through FIG. 5D by merging the openings 314 within the third slot regions 902 and oriented next to each other in a general shape of the third slots 904. Subsequent to forming the third slots 904, portions of the other insulative material 208 (FIG. 2) of the stack structures 204 of the first block region 304 and the second block region 306 relatively proximate the third slots 904 may be removed through the third slots 904 as part of a so-called “replacement gate” or “gate last” process. By way of non-limiting example, the portions of the other insulative material 208 (FIG. 2) may be removed by exposing the other insulative material 208 (FIG. 2) to an etchant (e.g., a wet etchant) comprising one or more of phosphoric acid, sulfuric acid, hydrochloric acid, nitric acid, or another material. In some embodiments, the portions of the other insulative material 208 (FIG. 2) are removed by exposing the other insulative material 208 (FIG. 2) to a so-called “wet nitride strip” comprising phosphoric acid.

Referring to FIG. 2 and FIG. 9, after removal of the portions of the other insulative material 208, additional conductive material 906 may be formed within the resulting void spaces. The additional conductive material 906 of some of the tiers 210 may serve as additional portions of the local word lines 110 and as extensions 112 of the global word lines 114. The additional conductive material 906 may be formed of and include any of the conductive materials and liners described above in regard to the conductive material 606 (FIG. 6). A material composition of the additional conductive material 906 may be substantially the same as a material composition of the conductive material 606, or the material composition of the additional conductive material 906 may be different than the material composition of the conductive material 606.

After forming the conductive material 606, the third slots 904 may be filled with a third dielectric material 908. The third dielectric material 908 may form a third slot structure 910. Accordingly, the third dielectric material 908 (e.g., the third slot structures 910) may physically separate (e.g., isolate) additional portions (e.g., in-tier control circuitry regions 348, support region 322) of horizontally neighboring (e.g., adjacent) blocks 106 from each other, and may also physically separate portions of the extensions 112 of the global word lines 114 of the microelectronic device 102 from each other. As shown in FIG. 9, the third slot structures 910 may horizontally overlap (e.g., be substantially horizontally aligned with) the first slot structures 406 and the second slot structures 610 in the Y-direction.

The third dielectric material 908 may be formed of and include any of the insulative materials described above in regard to the second dielectric material 608 (FIG. 6). A material composition of the third dielectric material 908 may be substantially the same as a material composition of the second dielectric material 608, or the material composition of the third dielectric material 908 may be different than the material composition of the second dielectric material 608.

As is depicted in FIG. 9, formation of the extensions 112 of the global word lines 114 and additional portions of the local word lines 110 provides connections to the source and/or drain structures 702 (e.g., the first semiconductor structures 810 and the second semiconductor structures 812 (FIGS. 8K and 8L)) of the thin film transistors 108 (FIG. 1). The local word lines 110 and/or the extensions 112 of the global word lines 114 may contact the source and/or drain structures 702 of the thin film transistors 108, and may accordingly facilitate electrical communication between memory cells within the memory array regions 310 of the block 106 and control logic circuitry of a microelectronic device to be formed from the microelectronic device structure 302.

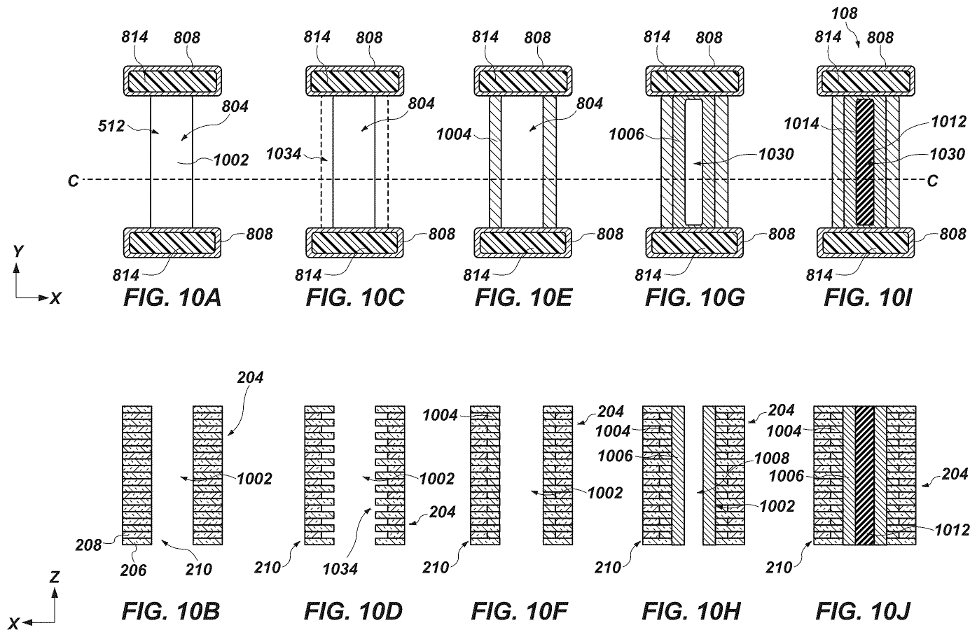

FIG. 10A through FIG. 10J include simplified, top-down views (FIGS. 10A, 10C, 10E, 10G, 10I) and simplified, vertical cross-sectional views (FIGS. 10B, 10D, 10F, 10H, 10J) showing different processing stages of forming additional portions of thin film transistors 108 (FIGS. 1, 8K, and 8L). FIG. 10A through FIG. 10L show processing stages that are subsequent to the formation of the extensions 112 of the global word lines 114 and the additional portions of the local word lines 110 described above in regard to FIG. 9. The simplified, vertical cross-sectional views shown in FIGS. 10B, 10D, 10F, 10H, and 10J are about line C-C shown in FIGS. 10A, 10C, 10E, 10G, and 10I, respectively. FIGS. 10A and 10B collectively depict a first processing stage in the process of forming the additional portions of the thin film transistors 108; FIGS. 10C and 10D collectively depict a second processing stage following the first processing stage; FIGS. 10E and 10F collectively depict a third processing stage following the second processing stage; FIGS. 10G and 10H collectively depict a fourth processing stage following the third processing stage; and FIGS. 10I and 10J collectively depict a fifth processing stage following the fourth processing stage. FIG. 10A through FIG. 10J show the formation of additional portions of thin film transistors 108 within horizontal area of a single merged opening 512; however, it is understood that the processes described in regard to FIG. 10A through FIG. 10J may be utilized to form additional portions of the thin film transistors 108 within horizontal areas of multiple merged openings 512 simultaneously and/or consecutively.

Referring collectively FIGS. 10A and 10B, remaining portions of the fill material 514 (FIGS. 8K and 8L) within the central elongated portion 804 of the merged opening 512 may be removed to form a channel trench 1002. The remaining portions of the fill material 514 may be removed through any of the removal processes described herein. For example, a mask material may be formed over the top surfaces of the stack structures 204 of the first block region 304 and the second block region 306 (e.g., on a top surface of the third preliminary deck structure 506 (FIG. 5A)), and the mask material may be patterned to form an opening horizontally aligned with the central elongated portion 804 of the merged openings 512 within the thin film transistor regions 402 (FIG. 4). The mask material may be patterned to include the patterned openings utilizing any suitable methodology. For instance, in some embodiments, a photoresist material is formed on or over the mask material, is patterned (e.g., photo exposed and developed), and then openings formed in the patterned photoresist material are extended into the mask material to form the patterned openings. The mask material may be removed during subsequent processing stages or may remain in a final device formed through the methods of the disclosure. The mask material may be formed of and include a dielectric material, such as a dielectric nitride material (e.g., silicide nitride).

The mask material and the patterned openings may be employed to remove the remaining portions of the fill material 514 within the central elongated portion 804 of the merged openings 512 to form the channel trench 1002 through one or more etch processes. For instance, the remaining portions of the fill material 514 may be removed using an etching process (e.g., an anisotropic etching process) that selectively removes exposed portions of the fill material 514 without removing portions of the insulative material 206 and the other insulative material 208. Additionally, the remaining portions of the fill material 514 may be removed using a directional etching process that does not significantly etch in horizontal directions (e.g., in the Y- and/or X-directions). Furthermore, the remaining portions of the fill material 514 within the central elongated portion 804 of respective ones of the merged openings 512 extending through the first preliminary deck structure 502 (FIG. 5E), the second preliminary deck structure 504 (FIG. 5E), and the third preliminary deck structure 506 (FIG. 5E) may be removed through a single etching process or multiple etching processes.

Referring to FIGS. 7, 10C, and 10D together, additional portions of the other insulative material 208 of respective tiers 210 of the stack structures 204 defining horizontal boundaries of the channel trench 1002 may be removed (e.g., recessed) to form additional horizontal recesses 1034 at vertical positions of the other insulative material 208 of the tiers 210. For example, portions of the other insulative material 208 of the tiers 210 may be removed using a selective etching process (e.g., isotropic etching process) that selectively removes exposed portions of the other insulative material 208 (e.g., dielectric nitride material) without substantially removing portions of the insulative material 206 (e.g., dielectric oxide material) of the tiers 210. In some embodiments, the additional portions of the other insulative material 208 are removed using a wet nitride removal process. In some embodiments, the additional portions of the other insulative material 208 of each of first preliminary deck structure 502 (FIG. 5E), the second preliminary deck structure 504 (FIG. 5E), and the third preliminary deck structure 506 (FIG. 5E) is removed at least substantially simultaneously. The additional horizontal recesses 1034 may be integral and continuous with the channel trench 1002.

Referring to FIGS. 7, 10E, and 10F together, channel material 1004 may be formed within the additional horizontal recesses 1034 (FIGS. 10B and 10C). As shown in FIG. 10F, the channel material 1004 may substantially fill respective ones of the additional horizontal recesses 1034 (FIG. 10C). Portions of the channel material 1004 within a horizontal area of the channel trench 1002 may be removed, such that the channel material 1004 is substantially confined within horizontal areas of the additional horizontal recesses 1034 (FIGS. 10B and 10C).

The channel material 1004 may be formed (e.g., deposited) through any of the deposition processes described herein. For instance, the channel material 1004 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In some embodiments, forming the channel material 1004 includes overfilling the vertical spaces between insulative material 206 of the tiers 210 of the stack structures 204 with the channel material 1004 and then removing any excess portions through one or more etching processes. For instance, the central elongated portion 804 of the merged openings 512, including the vertical spaces between insulative material 206 of the tiers 210 of the stack structures 204, may be filled with the channel material 1004, and excess portions of the channel material 1004 may be subsequently removed.

The channel material 1004 may be formed of and include one or more of a semiconductor material (at least one elemental semiconductor material, such as polycrystalline silicon; at least one III-V compound semiconductor material, at least one II-VI compound semiconductor material, at least one organic semiconductor material, GaAs, InP, GaP, GaN, other semiconductor materials) and an oxide semiconductor material. In some embodiments, the channel material 1004 includes amorphous silicon or polysilicon. In some embodiments, the channel material 1004 is formed of and includes doped semiconductor material.

Referring to FIGS. 7, 10G, and 10H together, a gate insulative liner 1006 may be formed within the channel trench 1002 of the merged openings 512. For example, a gate insulative liner 1006 may be formed to horizontally neighbor exposed surfaces of the insulative material 206 of the tiers 210 of the stack structure 204 and the exposed surfaces of the channel material 1004 at the vertical positions of the other insulative material 208 of the tiers 210 of the stack structure 204. Put another way, the gate insulative liner 1006 may be formed to line vertically oriented surfaces of the insulative material 206 and the channel material 1004 partially defining boundaries of the channel trench 1002 (or a remainder of the channel trench 1002).

The gate insulative liner 1006 may be formed (e.g., deposited) through any of the deposition processes described herein. For instance, the gate insulative liner 1006 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In additional embodiments, the gate insulative liner 1006 is formed (e.g., conformally deposited) inside and outside of the channel trenches 1002 and then portions of the gate insulative liner 1006 outside of the channel trenches 1002 are removed (e.g., by way of CMP) while portions of the gate insulative liner 1006 within the channel trenches 1002 are maintained. As is shown in FIG. 10H, bottom portions of the gate insulative liner 1006 lining the bottom of the channel trench 1002 may be removed through one or more subsequent etching processes. Additionally, within the XY plane, the gate insulative liner 1006 may have a generally annular shape (e.g., a generally block-O shape).

The gate insulative liner 1006 may be formed of and include insulative material such as, for example, one or more of dielectric oxide material (e.g., phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide), dielectric nitride material (e.g., silicon nitride (Si₃N₄)), dielectric oxynitride material (e.g., silicon oxynitride), dielectric carbon nitride material (e.g., silicon carbon nitride (SiCN)), and dielectric carboxynitride material (e.g., silicon carboxynitride (SiOCN)). In some embodiments, the gate insulative liner 1006 is formed of and includes silicon dioxide.

As is shown in FIGS. 10G and 10H, the gate insulative liner 1006 may define a gate space 1008 within the channel trench 1002. For instance, a remaining space within the channel trench 1002 not occupied by the gate insulative liner 1006 may form the gate space 1008. The horizontal boundaries of the gate space 1008 may be defined by an inner side surface 1010 (e.g., an inner sidewall) of the gate insulative liner 1006.

Referring to FIGS. 101 and 10J together, a gate material 1012 may be formed within the gate space 1008 (FIGS. 10G and 10H). For example, the gate material 1012 may be formed to substantially fill the gate space 1008 and to horizontally neighbor the inner side surface 1010 (FIGS. 10G and 10H) of the gate insulative liner 1006.

The gate material 1012 may be formed (e.g., deposited) through any of the deposition processes described herein. For instance, the gate material 1012 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In additional embodiments, the gate material 1012 is formed inside and outside of the gate spaces 1008 and then portions of the gate material 1012 outside of the gate spaces 1008 are removed (e.g., by way of CMP) while the portion of the gate material 1012 within the gate spaces 1008 is maintained.

The gate material 1012 may be formed of and include conductive material. By way of non-limiting example, the gate material 1012 may be formed of and include one or more of W, Ru, Mo, TiN_{y}, or any other metallic material. The gate material 1012 may form gates 1030 of the thin film transistors 108.

Referring still to FIGS. 101 and 10J, the thin film transistors 108 may respectively have a horizontal length in the X-direction within a range of from about 1.0 μm to about 2.0 μm. For example, the thin film transistors 108 may respectively have a horizontal length in the X-direction of about 1.5 μm. Additionally, the thin film transistors 108 may respectively have a horizontal width in the Y-direction within a range of from about 200 nm to about 300 nm. For instance, the thin film transistors 108 may respectively have a horizontal width in the Y-direction of about 250 nm. Furthermore, the gate material 1012 (e.g., the gate structure) of the thin film transistors 108 may have a horizontal length in the X-direction within a range of from about 0.5 μm to about 0.8 μm. For example, the gate material 1012 (e.g., the gate) of the thin film transistor 108 may have a horizontal length in the X-direction of about 0.65 μm. Moreover, the gate material 1012 may have a horizontal width in the Y-direction within a range of from about 30 nm to about 50 nm. For instance, the gate material 1012 may have a horizontal width in the Y-direction of about 40 nm. Also, the gate insulative liner 1006 may have a horizontal width in the Y-direction within a range of from about 30 nm to about 50 nm. For example, the gate insulative liner 1006 may have a horizontal width in the Y-direction of about 40 nm. Also, the channel material 1004 may have a horizontal width in the Y-direction within a range of from about 10 nm to about 30 nm. For instance, the channel material 1004 may have a horizontal width in the Y-direction of about 20 nm.

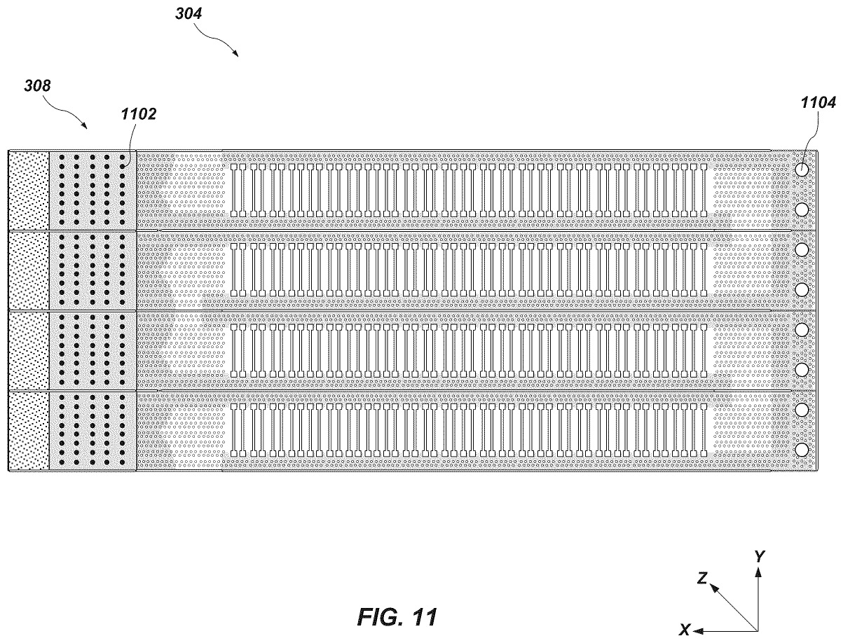

FIG. 11 shows a top schematic view of the first block region 304 following the processing stages previously described with reference to FIGS. 9 and 10A through 10J, according to one or more embodiments. Referring to FIG. 3A and FIG. 11 together, as noted above, the SGD contact regions 308 of both the first block region 304 and the second block region 306 may include dummy pillars 328 extending through the first block region 304 and the second block region 306 in the Z-direction. Additionally, as mentioned above, the word line contact openings 324 may provide access to the individual steps of the staircase structures 116 within the staircase structure region 118, and may be filled with a second sacrificial material 326.

Subsequent to the processes described above in regard to FIG. 10A through FIG. 10E, material(s) forming the dummy pillars 328 and the second sacrificial material 326 within the word line contact openings 324 may be removed through any of the removal processes described herein. Additionally, the resulting voids may be filled with conductive material. For instance, the resulting voids may be filled with tungsten (W). Filling the voids resulting from the removal of the dummy pillars 328 may form SGD contacts 1102. Filling the voids resulting from the removal of the second sacrificial material 326 may form word line contacts 1104 (e.g., global word line contacts).

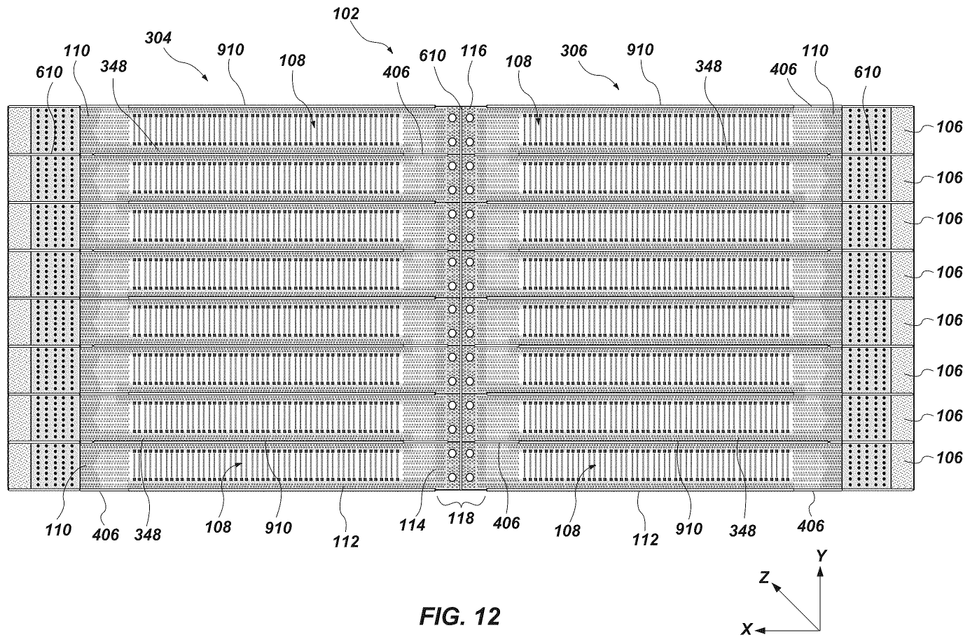

FIG. 12 shows a top schematic view of the microelectronic device 102 (including first block region 304, the second block region 306, and the staircase structure region 118 thereof) subsequent to the processes described above in regard to FIG. 1 through FIG. 11, according to one or more embodiments.

FIG. 13 shows a partial cutaway perspective view of a portion of a microelectronic device 1302 (e.g., a memory device, such as a dual deck 3D NAND Flash memory device) that may be formed according to the processes described above in regard to FIG. 1 through FIG. 12. For example, the microelectronic device 1302 may include the global word lines 114, the extensions 112, the local word lines 110, the deck portions (e.g., first block region 304 and/or second block region 306), the blocks 106, the thin film transistor regions 402, and the thin film transistors 108 (FIG. 1) described above.

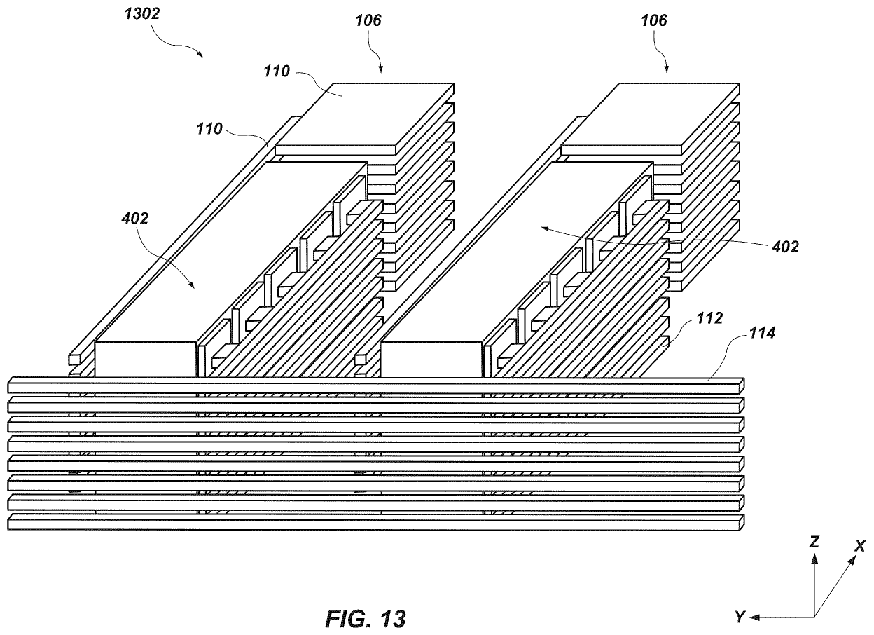

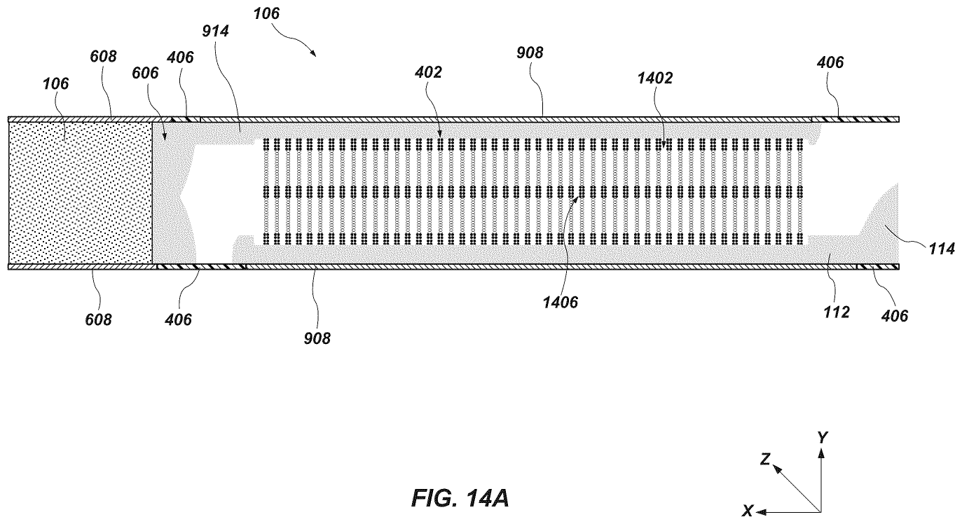

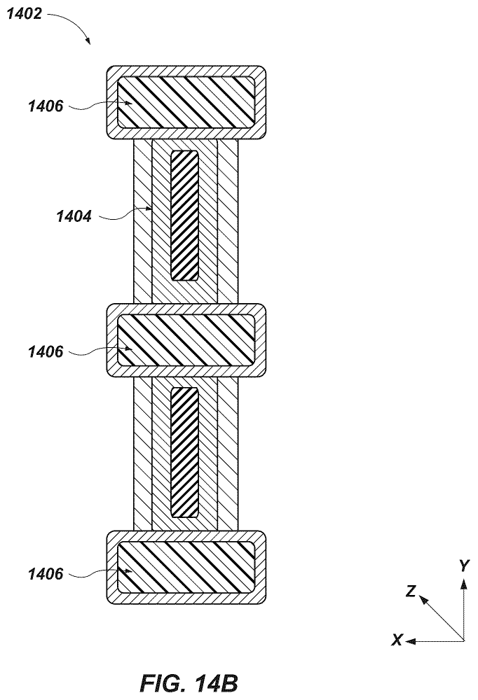

FIG. 14A shows top-down view of an arrangement of multi-gate thin film transistors 1402 within a thin film transistor region 402 of a microelectronic device (e.g., the microelectronic device 1302 (FIG. 13)), according to one or more embodiments. FIG. 14B shows a schematic diagram of one of the multi-gate thin film transistors 1402 shown in FIG. 14A. The multi-gate thin film transistors 1402 configurations shown in FIGS. 14A and 14B may be formed using the processes previously described herein with reference to FIGS. 1 through 12. Referring to FIG. 14A and FIG. 14B together, an individual multi-gate thin film transistor 1402 may include a generally linear arrangement of multiple source and/or drain structures 1406 and channel structures 1404 horizontally positioned next to each other. Furthermore, the multiple source and/or drain structures 1406 and channel structures 1404 may be horizontally position relative to one another in an alternating pattern (e.g., source and/or drain structure 1406, channel structure 1404, source and/or drain structure 1406, channel structure 1404, etc.).

The source and/or drain structures 1406 may include any of the structures described above in regard to FIGS. 8A through 8L and the first semiconductor structure 810 and the second semiconductor structure 812. Furthermore, the channel structures 1404 may include any of the channel structures 1014 described above in regard to FIG. 10A through FIG. 10J.

The multi-gate thin film transistors 1402 may provide thin film transistors 108 (FIG. 10I) in series, and having thin film transistors 108 in series, may provide protection against shorts between source and/or drain structures 1406. Furthermore, all of the gates 1030 (FIG. 10E) of the multi-gate thin film transistors 1402 may be driven by a same BlockSelect signal. Additionally, in some embodiments, center source and/or drain structures 1406 of neighboring multi-gate thin film transistors 1402 are shorted together.

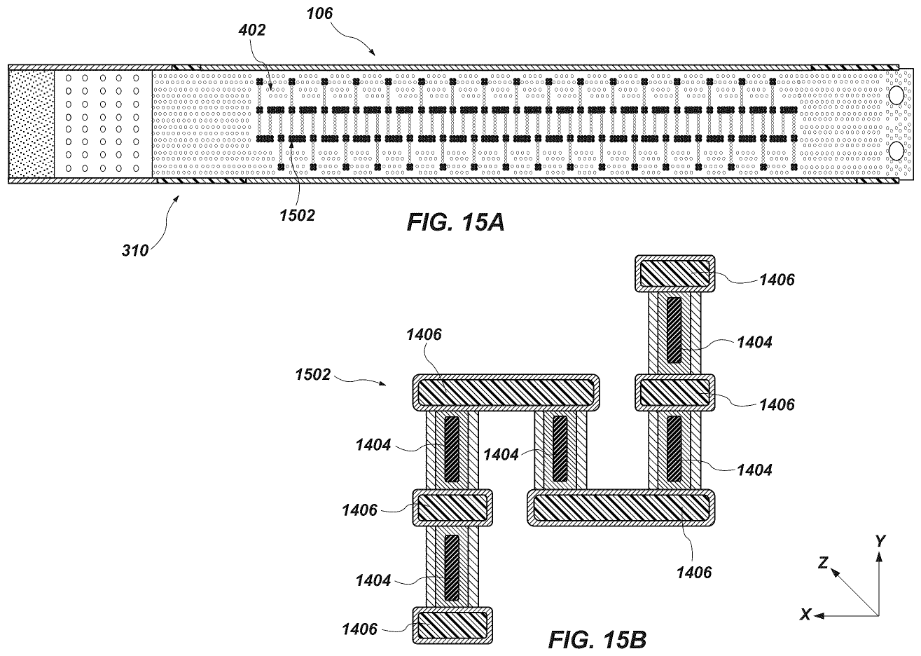

FIG. 15A shows a top-down view of an arrangement of multi-gate thin film transistors 1502 within a thin film transistor region 402 of a microelectronic device (e.g., the microelectronic device 1302 (FIG. 13)), according to one or more embodiments. FIG. 15B shows a schematic diagram of one of the multi-gate thin film transistors 1502 shown in FIG. 14A. The multi-gate thin film transistor 1502 configurations shown in FIGS. 15A and 15B may be formed using the processes previously described herein with reference to FIGS. 1 through 12. Referring to FIG. 15A and FIG. 15B together, an individual multi-gate thin film transistor 1502 may include a generally serpentine-shaped arrangement of multiple source and/or drain structures 1406 and channel structures 1404. Furthermore, the multiple source and/or drain structures 1406 and channel structures 1404 may be oriented relative to one another in an alternating pattern (e.g., source and/or drain structure 1406, channel structure 1404, source and/or drain structure 1406, channel structure 1404, etc.) along an overall, non-linear (e.g., serpentine) path of the multi-gate thin film transistor 1502.

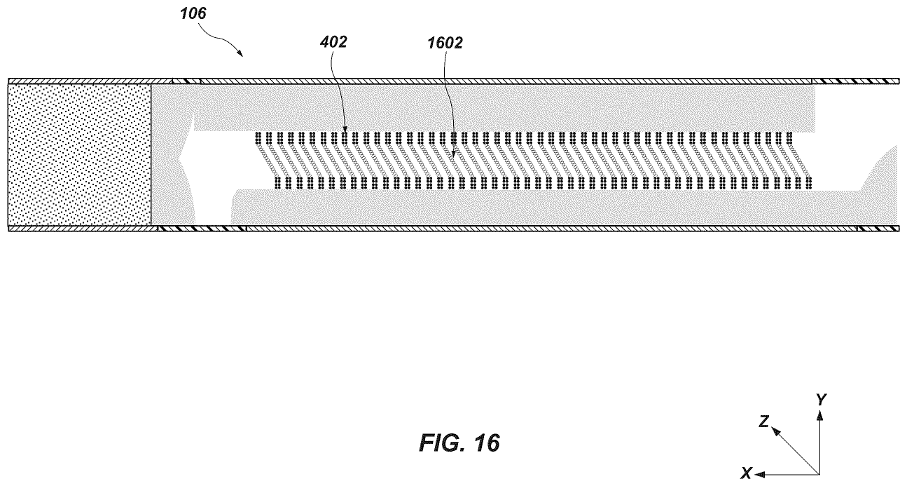

FIG. 16 shows a top-down view of an arrangement of thin film transistors 1602 within a thin film transistor region 402 of a microelectronic device (e.g., the microelectronic device 1302 (FIG. 13)), according to one or more embodiments. The thin film transistor 1602 configurations shown in FIG. 16 may be formed using the processes previously described herein with reference to FIGS. 1 through 12. As shown in FIG. 16, the thin film transistors 1602 of the thin film transistor region 402 may be oriented at an acute angle relative to the Y-axis. Put another way, horizontal axes of the thin film transistors 1602 within the XY plane may be oriented at an acute angle relative to horizontal axes of the extensions 112 of the global word lines 114 and relative to horizontal axes of the local word lines 110. In some embodiments, the acute angle is within the range of about 20° and about 89°. For instance, the thin film transistors 1602 of the thin film transistor region 402 may be oriented at 45° angle relative to the Y-axis.

Orienting the thin film transistors 1602 at an acute angle relative to longitudinal axes of the extensions 112 of the global word lines 114 and relative to longitudinal axes of the local word lines 110 enables the thin film transistors 1602 to have longer lengths relative to an overall width of the block 106 in the Y-direction. Additionally, horizontal thicknesses in the Y-direction of the extensions 112 of the global word lines 114 and of portions (e.g., extension portions) of the local word lines 110 of the blocks 106 can be increased without decreasing horizontal lengths of the thin film transistors 1602. Moreover, orienting the thin film transistors 1602 at an acute angle relative to horizontal axes of the extensions 112 of the global word lines 114 and relative to longitudinal axes of the local word lines 110 reduces an effect block width has on thin film transistor 1602 length.

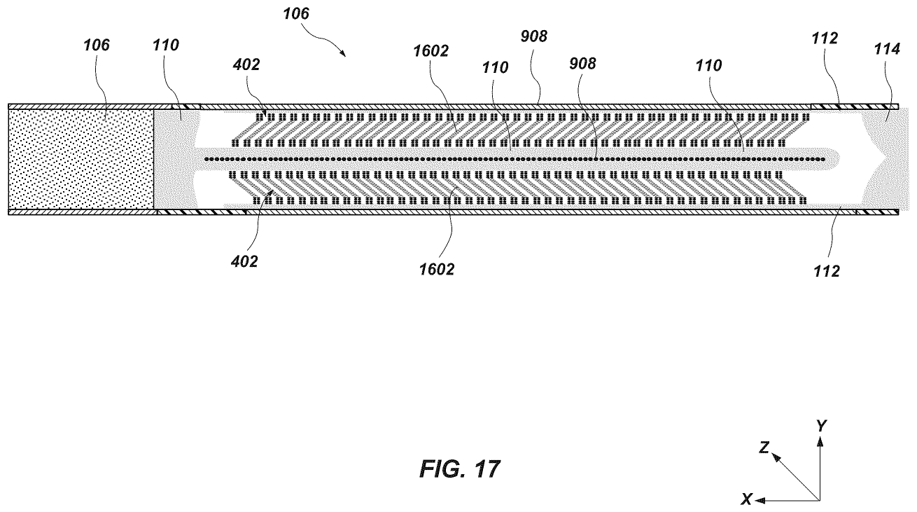

FIG. 17 a top-down view of an additional arrangement of thin film transistors 1602 within a thin film transistor region 402 of a microelectronic device (e.g., the microelectronic device 1302 (FIG. 13)), according to one or more embodiments. The thin film transistor 1602 configurations shown in FIG. 17 may be formed using the processes previously described herein with reference to FIGS. 1 through 12. As described in regard to FIG. 16, the thin film transistors 1602 of FIG. 17 may be angled relative to the horizontal axes of the extensions 112 of the global word lines 114 and relative to the horizontal axes of the local word lines 110. Furthermore, FIG. 17 shows two rows of the thin film transistors 1602 at opposing sides of a local word line 110, where the thin film transistors 1602 are angled relative to horizontal axes of the extensions 112 of the global word lines 114, and relative to the horizontal axes of the local word lines 110. In the example depicted in FIG. 17, the thin film transistors 1602 are horizontally angled by about 60°.

Having two neighboring rows of thin film transistors 1602, where the thin film transistors 1602 are angled relative to horizontal axes of the extensions 112 of the global word lines 114, and relative to horizontal axes of the local word lines 110 within a single block 106, may increase driving capability.

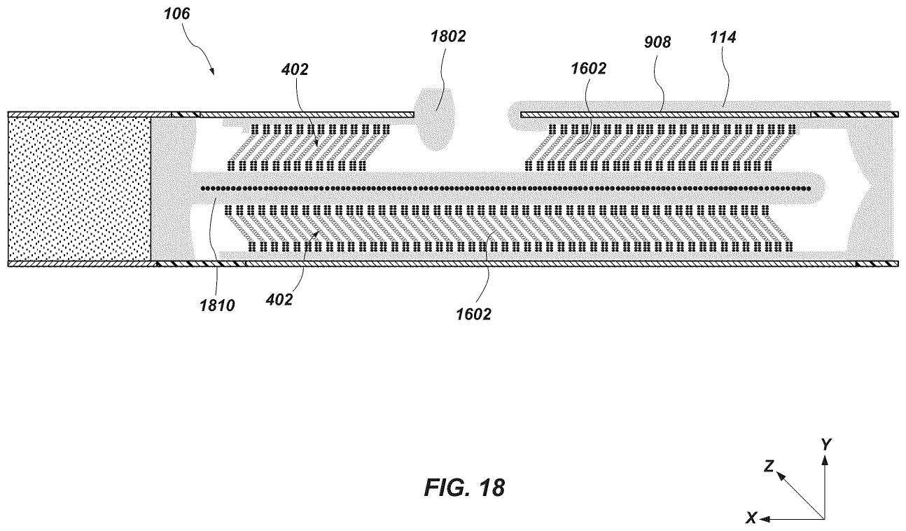

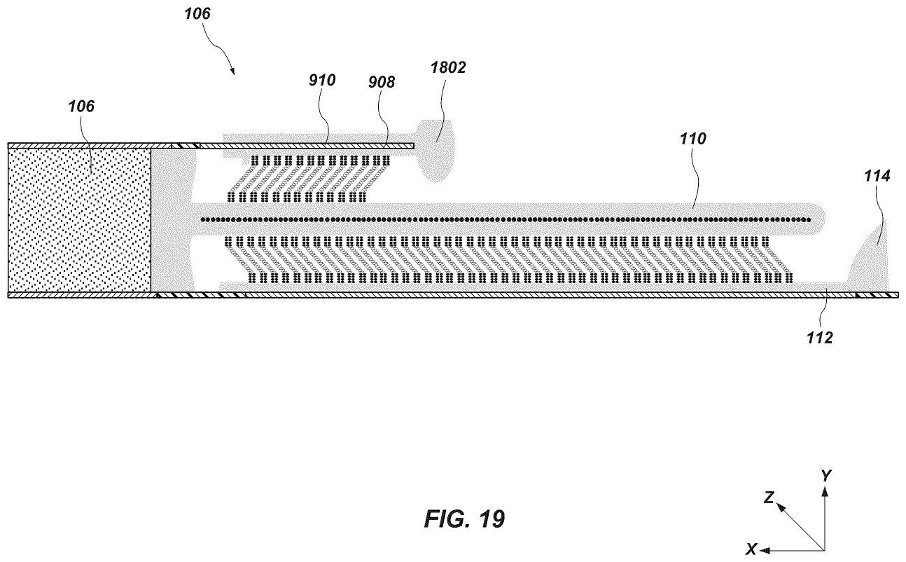

FIG. 18 and FIG. 19 show top-down views of further arrangements of thin film transistors 1602 within a thin film transistor region 402 of a microelectronic device (e.g., the microelectronic device 1302 (FIG. 13)), according to additional embodiments. The thin film transistor 1602 configurations shown in FIGS. 18 and 19 may be formed using the processes previously described herein with reference to FIGS. 1 through 12. As described in regard to FIG. 16, the thin film transistors 1602 of FIGS. 18 and 19 are angled relative to horizontal axes of the extensions 112 of the global word lines 114 and relative to horizontal axes of the local word lines 110.

As shown in FIG. 18 and FIG. 19, the processes described herein facilitate formation of a connection to an additional string driver 1802 within a horizontal span, in the X-direction, of the in-tier control circuitry region 348 (FIG. 3A) of the block 106. Such an additional string driver 1802 may avoid having local word lines 110 floating when unselected. Furthermore, the additional string driver 1802 may exhibit different voltages than the local word lines 110 and the global word lines 114, facilitating additional functions for the block 106 and associated microelectronic device (e.g., the microelectronic device 1302 (FIG. 13)).

Thus, in accordance with some embodiments of the disclosure, a method of forming a microelectronic device includes forming a stack structure comprising a vertically alternating sequence of insulative structures and other insulative structures arranged in tiers, forming a pattern of openings in the stack structure, the openings extending into the stack structure from an uppermost surface of the stack structure, the pattern of openings comprising first groups of openings respectively including openings substantially linearly arranged relative to one another; and second groups of openings respectively including additional openings horizontally arranged relative to one another in a dog-bone shape merging the openings within respective first groups of openings together to form slots; and merging the additional openings within respective second group of openings to form merged openings individually comprising, each merged opening comprising a central elongated portion and two wide end portions at opposing horizontal ends of the central elongated portion.

Moreover, in accordance with embodiments of the disclosure, a method of forming a microelectronic device. The method may include forming a first block region and a second block region separated from one another by a staircase structure coupled to global word lines; forming a pattern of openings vertically extending through a vertically alternating sequence of insulative material and additional insulative material within in each of the first block region and the second block region, the pattern of openings comprising groups of openings; merging openings within respective groups of openings to form merged openings; and forming thin film transistors within the merged openings.

Additionally, in accordance with embodiments of the disclosure, a microelectronic device includes a stack structure including tiers respectively including a local word line structure, global word lines vertically overlapping stack structure, and transistors at vertical positions of the tiers of the stack structure. Each of the transistors may respectively include a first source/drain region coupled to one of the global word lines; a second source/drain region coupled to one of the local word lines; a channel region horizontally extending from the first source/drain region to the second source/drain region, and a gate horizontally neighboring the channel region. The channel region may include a relatively smaller width than each of the first source/drain region and the second source/drain region in a first horizontal direction; and a relatively larger length than each of the first source/drain region and the second source/drain region in a second horizontal direction different than the first horizontal direction.

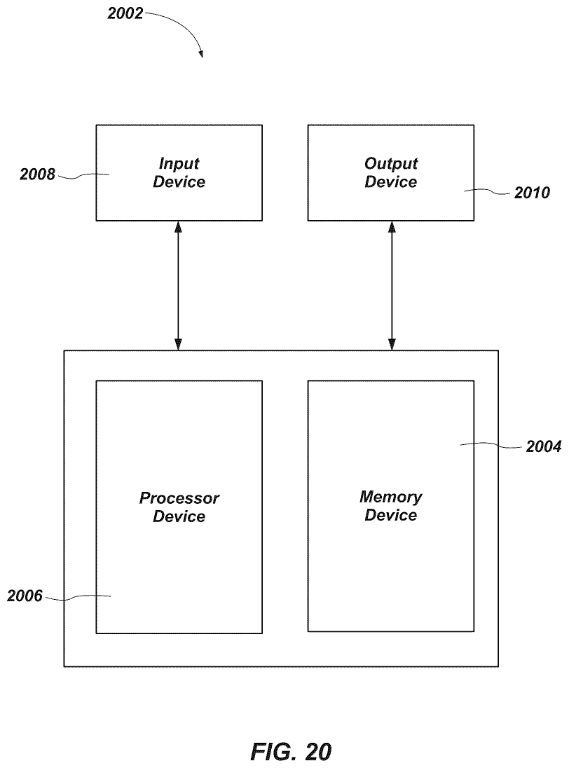

FIG. 20 is a block diagram of an electronic system 2002, in accordance with embodiments of the disclosure. The electronic system 2002 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 2002 includes at least one memory device 2004. The memory device 2004 may include, for example, an embodiment of a microelectronic device structure and/or a microelectronic device previously described within with respect to one of more of FIGS. 1 and 12 through 19.

The electronic system 2002 may further include at least one electronic signal processor device 2006 (often referred to as a “microprocessor”). The electronic signal processor device 2006 may, optionally, include an embodiment of a microelectronic device structure and/or a microelectronic device previously described within with respect to one of more of FIGS. 1 and 12 through 19. The electronic system 2002 may further include one or more input devices 2008 for inputting information into the electronic system 2002 by a user, such as, for example, a mouse or other pointing device, a keyboard, a touchpad, a button, or a control panel. The electronic system 2002 may further include one or more output devices 2010 for outputting information (e.g., visual or audio output) to a user such as, for example, a monitor, a display, a printer, an audio output jack, a speaker, etc. In some embodiments, the input device 2008 and the output device 2010 may comprise a single touchscreen device that can be used both to input information to the electronic system 2002 and to output visual information to a user. The input device 2008 and the output device 2010 may communicate electrically with one or more of the memory device 2004 and the electronic signal processor device 2006.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A method of forming a microelectronic device, the method comprising:
forming a stack structure comprising a vertically alternating sequence of insulative structures and other insulative structures arranged in tiers;
forming a pattern of openings in the stack structure, the openings extending into the stack structure from an uppermost surface of the stack structure, the pattern of openings comprising:
first groups of openings respectively including openings substantially linearly arranged relative to one another; and
second groups of openings respectively including additional openings horizontally arranged relative to one another in a dog-bone shape;
merging the openings within respective first groups of openings together to form slots; and
merging the additional openings within respective second group of openings to form merged openings individually comprising:
a central elongated portion; and
two wide end portions at opposing horizontal ends of the central elongated portion.

2. The method of claim 1, further comprising:
recessing portions of the other insulative structures defining horizontal boundaries of the wide end portions of the merged openings to form void spaces at vertical positions of the other insulative structures; and
forming semiconductor material within the void spaces.

3. The method of claim 2, wherein forming the semiconductor material within void spaces comprises forming generally horizontally annular-shaped semiconductor structures.

4. The method of claim 2, further comprising:
recessing additional portions of the other insulative structures defining horizontal boundaries of the central elongated portion of the merged openings to form additional void spaces at the vertical positions of the other insulative structures; and
forming a channel material within the additional void spaces.

5. The method of claim 4, further comprising:
lining the channel material with a gate insulative liner; and
forming a gate material within a gate space at least partially defined by inner side surface of the gate insulative liner.

6. The method of claim 1, further comprising:
removing portions of the other insulative structures through the slots to form void spaces at vertical positions of the other insulative structures; and
forming conductive structures within the void spaces.

7. The method of claim 6, wherein forming the conductive structures comprises forming portions of local word lines and global word lines.

8. The method of claim 6, further comprising filling one or more of the slots with dielectric material to form slot structures separating blocks of the stack structure from one another.

9. The method of claim 1, wherein merging the openings within respective first groups of openings and merging the additional openings within respective second groups of openings comprises:
removing the insulative structures horizontally interposed between the openings within the respective first groups of openings and within the respective second groups of openings using a first etch process; and
removing the other insulative structures horizontally interposed between the openings within the respective first groups of openings and the respective second groups of openings using a second etch process.

10. A method of forming a microelectronic device, the method comprising:
forming a first block region and a second block region separated from one another by a staircase structure coupled to global word lines;
forming a pattern of openings vertically extending through a vertically alternating sequence of insulative material and additional insulative material within in each of the first block region and the second block region, the pattern of openings comprising groups of openings;
merging openings within respective groups of openings to form merged openings; and
forming thin film transistors within the merged openings.

11. The method of claim 10, further comprising forming each of the merged openings to include:
a central portion elongated in a first horizontal direction; and
two end portions at opposing horizontal ends of the central portion in the first horizontal direction and respectively relatively wider than the central portion in a second horizontal direction orthogonal to the first horizontal direction.

12. The method of claim 11, wherein forming the thin film transistors within the merged openings comprises:
selectively removing portions of the additional insulative material defining horizontal boundaries of the two end portions of each of the merged openings to form horizontal recesses;
forming semiconductor material within the horizontal recesses to form source structures and drain structures of the thin film transistors;
selectively removing additional portions of the additional insulative material defining horizontal boundaries of the central portion of each of the merged openings to form additional horizontal recesses;
forming channel material within the additional horizontal recesses;
lining inner side surfaces of the channel material with a gate insulative liner; and
forming a gate material on inner side surfaces of the gate insulative liner to form gates of the thin film transistors.

13. The method of claim 10, wherein forming a pattern of openings comprises forming additional groups of openings vertically extending through the vertically alternating sequence of the insulative material and the additional insulative material within in each of the first block region and the second block region, the openings of respective ones of the additional groups of openings substantially linearly arranged relative to one another.

14. The method of claim 13, wherein the additional groups of openings at least partially define horizontal boundaries of blocks within each of the first block region and the second block region.

15. The method of claim 13, further comprising merging the openings of the respective ones of additional groups of openings to form slots.

16. The method of claim 10, wherein forming the thin film transistors comprises forming multi-gate thin film transistors.

17. A microelectronic device, comprising:
a stack structure comprising tiers respectively including a local word line structure;
global word lines vertically overlapping the stack structure; and
transistors at vertical positions of the tiers of the stack structure and respectively comprising:
a first source/drain region coupled to one of the global word lines;
a second source/drain region coupled to a local word line; and
a channel region horizontally extending from the first source/drain region to the second source/drain region, the channel region comprising:
a relatively smaller width than each of the first source/drain region and the second source/drain region in a first horizontal direction; and
a relatively larger length than each of the first source/drain region and the second source/drain region in a second horizontal direction different than the first horizontal direction; and
a gate horizontally neighboring the channel region.

18. The microelectronic device of claim 17, wherein, for respective ones of the transistors:
each of the first source/drain region and the second source/drain region has a generally annular horizontal cross-sectional shape; and
the channel region has an additional, generally annular horizontal cross-sectional shape.

19. The microelectronic device of claim 17, wherein, for respective ones of the transistors, the gate thereof vertically extends through the stack structure and is shared with other respective ones of the transistors.

20. The microelectronic device of claim 17, wherein second horizontal direction is acutely angled relative to the first horizontal direction.
